(19) United States
(12) Patent Application Publication
(10) Pub. No.: US 2024/0266188 A1
(43) Pub. Date: Aug. 8, 2024

(54) SEMICONDUCTOR PACKAGE AND METHOD OF FABRICATING THE SAME

(71) Applicant: Samsung Electronics Co., Ltd., Suwon-si (JP)

(72) Inventors: OKSEON YOON, Suwon-si (KR); KISEOK KIM, Suwon-si (KR); JIHYE SHIM, Suwon-si (KR)

(21) Appl. No.: 18/375,812

(22) Filed: Oct. 2, 2023

(30) Foreign Application Priority Data
Feb. 6, 2023 (KR) 10-2023-0015752

(51) Int. Cl. H01L 21/48

(52) U.S. Cl. CPC H01L 21/4853; H01L 23/49816; H01L 23/5383; H01L 24/16; H01L 25/105; H01L 2224/16227

(57) ABSTRACT

A method of fabricating a semiconductor package may include providing a substrate, forming a seed layer to cover a top surface of the substrate, sequentially stacking a sacrificial layer and a photoimageable layer on the seed layer, forming a penetration hole to penetrate the photoimageable layer and the sacrificial layer and expose the seed layer, forming a conductive post in the penetration hole, performing a first process to remove at least a portion of the sacrificial layer, performing a second process to remove the photoimageable layer, and patterning or removing the seed layer.

### CROSS-REFERENCE TO RELATED APPLICATIONS

This U.S. non-provisional patent application claims priority under 35 U.S.C. § 119 to Korean Patent Application No. 10-2023-0015752, filed on Feb. 6, 2023, in the Korean Intellectual Property Office, the entire contents of which are hereby incorporated by reference.

### BACKGROUND OF THE INVENTION

The present disclosure relates to a semiconductor package and a method of fabricating the same, and in particular, to a semiconductor package, which includes a redistribution substrate and a conductive post, and a method of fabricating the same.

A semiconductor package is configured to easily use an integrated-circuit chip as a part of an electronic product. Typically, the semiconductor package includes a printed circuit board (PCB) and a semiconductor chip, which is mounted on the PCB and is electrically connected to the PCB using bonding wires or bumps. As the electronics industry advances, various studies are being conducted to develop a highly reliable, highly integrated, and compact semiconductor package.

With recent advancements in the electronics industry, there is a growing demand for high-performance, high-speed, and compact electronic components. As the integration density of semiconductor chips increases, their size gradually decreases. However, when the size of the semiconductor chip is reduced, it becomes increasingly difficult to attach many solder balls to the semiconductor chip and to handle and test the solder balls. In addition, it is generally necessary to diversify a board according to the size of a semiconductor chip, and this leads to other challenging problems. In response to this trend, packaging technologies of mounting a plurality of semiconductor chips in a single package are being developed. One example is a fan-out wafer-level package (FO-WLP). In the FO-WLP, mold-through vias (MTVs) are used to electrically connect redistribution patterns, which are placed on or under a semiconductor chip, and this may allow for vertical stacking of boards mounted with the semiconductor chips. However, there is a difficulty in constructing a wiring structure or dissipating heat, particularly when a plurality of semiconductor chips are integrated on a single package.

### SUMMARY

Embodiments of the inventive concept provide a method of reducing a failure rate in a process of fabricating a semiconductor package and a semiconductor package fabricated thereby.

Embodiments of the inventive concept provide a semiconductor package, which has an improved electric connection structure and high driving stability, and a method of fabricating the same.

According to an embodiment of the inventive concept, a method of fabricating a semiconductor package may include providing a substrate, forming a seed layer to cover a top surface of the substrate, sequentially stacking a sacrificial layer and a photoimageable layer on the seed layer, forming a penetration hole to penetrate the photoimageable layer and the sacrificial layer and expose the seed layer, forming a conductive post in the penetration hole, performing a first process to remove at least a portion of the sacrificial layer, performing a second process to remove the photoimageable layer, and patterning or removing the seed layer.

According to an embodiment of the inventive concept, a method of fabricating a semiconductor package may include providing a substrate, sequentially stacking a sacrificial layer and a photoimageable layer on the substrate, forming a penetration hole to penetrate the photoimageable layer and the sacrificial layer, forming a conductive post in the penetration hole, performing a first process on the sacrificial layer to weaken an adhesive strength between the sacrificial layer and the substrate, and performing a second process to remove the sacrificial layer and the photoimageable layer.

According to an embodiment of the inventive concept, a method of fabricating a semiconductor package may include providing a substrate, sequentially stacking a sacrificial layer and a photoimageable layer on the substrate, forming a penetration hole to penetrate the photoimageable layer and the sacrificial layer, a width of the penetration hole in the sacrificial layer being larger than a width of the penetration hole in the photoimageable layer, forming a conductive post in the penetration hole, and performing a strip process, in which the same dissolving solution is used, to remove the photoimageable layer and the sacrificial layer. In the strip process, the sacrificial layer may be fully removed before fully removing the photoimageable layer.

According to an embodiment of the inventive concept, a semiconductor package may include a first redistribution substrate, a semiconductor chip on the first redistribution substrate, a mold layer on the first redistribution substrate and enclosing the semiconductor chip, a second redistribution substrate on the mold layer, and a conductive post at a side of the semiconductor chip and connecting the first redistribution substrate to the second redistribution substrate. The conductive post may include a first post and a second post on the first post. A maximum horizontal width of the first post may be larger than a maximum horizontal width of the second post, and a first height of the first post may be smaller than a second height of the second post.

### BRIEF DESCRIPTION OF THE DRAWINGS

FIG. 1 is a sectional view illustrating a semiconductor package according to an embodiment of the inventive concept.

FIGS. 2 to 6 are enlarged sectional views illustrating a portion ‘A’ of FIG. 1, according to embodiments of the inventive concept.

FIG. 7 is a sectional view illustrating a semiconductor package according to an embodiment of the inventive concept.

FIGS. 8 to 12 are enlarged sectional views illustrating a portion ‘B’ of FIG. 7, according to embodiments of the inventive concept.

FIGS. 13A to 25A are sectional views illustrating a method of fabricating a semiconductor package, according to an embodiment of the inventive concept.

FIGS. 13B to 25B are enlarged sectional views illustrating portions ‘C’ of FIGS. 13A to 25A.

### DETAILED DESCRIPTION

Example embodiments of the inventive concepts will now be described more fully with reference to the accompanying drawings, in which example embodiments are shown.

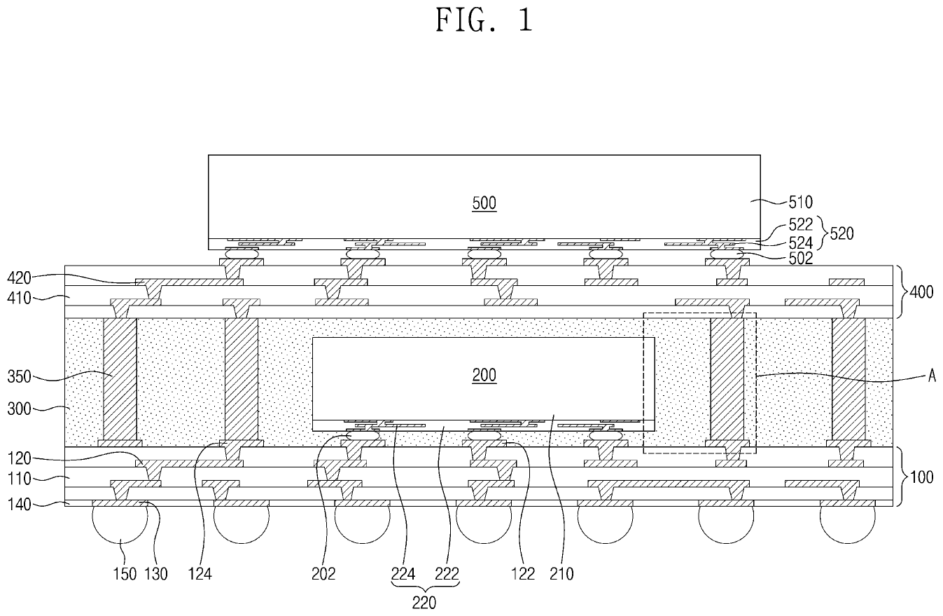

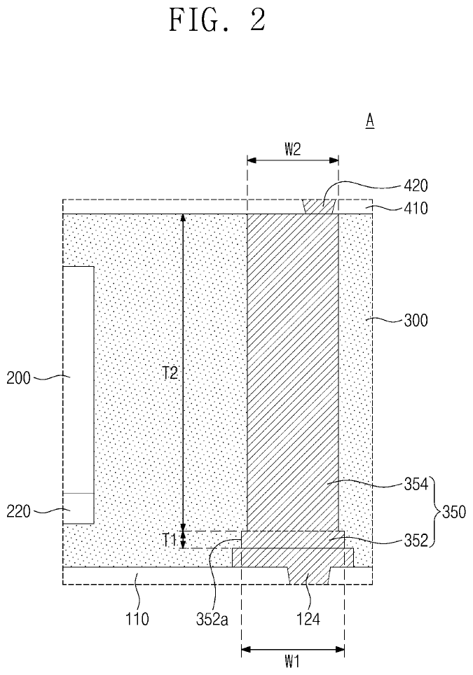

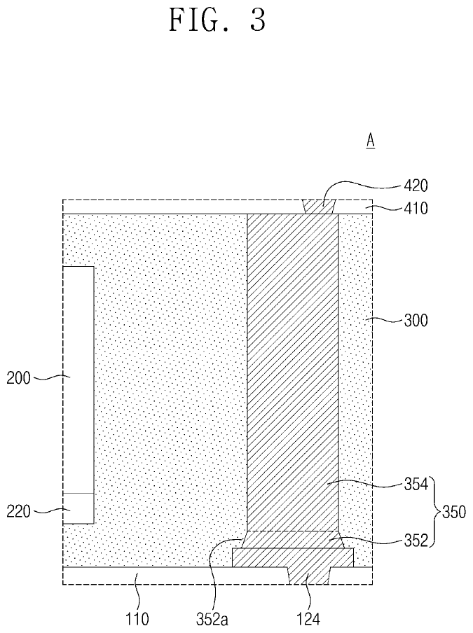

FIG. 1 is a sectional view illustrating a semiconductor package according to an embodiment of the inventive concept. FIGS. 2 to 6 are enlarged sectional views illustrating a portion ‘A’ of FIG. 1, according to different examples.

Referring to FIGS. 1 and 2, a first redistribution substrate 100 may be provided. The first redistribution substrate 100 may be a substrate that is used for redistribution of an interconnection structure. For example, the first redistribution substrate 100 may include at least two first substrate interconnection layers. Each of the first substrate interconnection layers may include a first substrate insulating pattern 110 and a first substrate interconnection pattern 120 in the first substrate insulating pattern 110. The first substrate interconnection pattern 120 of one of the first substrate interconnection layers may be electrically connected to the first substrate interconnection pattern 120 of another first substrate interconnection layer adjacent thereto.

The first substrate insulating pattern 110 may be formed of or include at least one of insulating polymers or photoimageable polymers (e.g., photoimageable dielectric (PID) materials). For example, the photoimageable polymers may be or may include at least one of photoimageable polyimide (PI), polybenzoxazole (PBO), phenol-based polymers, or benzocyclobutene-based polymers. Alternatively, the first substrate insulating pattern 110 may include another insulating material. For example, the first substrate insulating pattern 110 may be formed of or include at least one of silicon oxide (SiO), silicon nitride (SiN), silicon oxynitride (SiON), or insulating polymers.

The first substrate interconnection pattern 120 may be provided on the first substrate insulating pattern 110. On the first substrate insulating pattern 110, the first substrate interconnection pattern 120 may extend horizontally. The first substrate interconnection pattern 120 may be provided on a top surface of the first substrate insulating pattern 110. The first substrate interconnection pattern 120 may extend above the top surface of the first substrate insulating pattern 110. The first substrate interconnection pattern 120 on the first substrate insulating pattern 110 may be covered with another one of the first substrate insulating patterns 110 thereon. The first substrate interconnection pattern 120, which is provided on the uppermost one of the first substrate interconnection layers, may be used as substrate pads, to which a first semiconductor chip 200 and conductive posts 350 to be described below are coupled. For example, the first substrate interconnection pattern 120, which is provided on the uppermost one of the first substrate interconnection layers, may include first substrate pads 122, on which the first semiconductor chip 200 is mounted, and second substrate pads 124, to which the conductive posts 350 are coupled. As described above, the first substrate interconnection pattern 120 may be used as a pad portion or a wire portion of the first substrate interconnection layer. For example, the first substrate interconnection pattern 120 may be an element that is used for horizontal redistribution of the first redistribution substrate 100. The first substrate interconnection pattern 120 may include or be formed of a conductive material. For example, the first substrate interconnection pattern 120 may be formed of or include at least one of metallic materials (e.g., copper (Cu)).

The first substrate interconnection pattern 120 may have a damascene structure. For example, the first substrate interconnection pattern 120 may include a via portion that extends downward from a bottom surface of a horizontally-extending wiring portion formed on an underlying first substrate insulating pattern 110. The via portions may be used to vertically connect the first substrate interconnection patterns 120, which are respectively provided in adjacent ones of the interconnection layers, to each other. Alternatively, the via portion may be used to connect the first substrate interconnection pattern 120 in the lowermost one of the interconnection layers to outer pads 130, which will be described below. For example, a via portion may extend from the bottom surface of the first substrate interconnection pattern 120 to penetrate the first substrate insulating pattern 110 and may be coupled to a top surface of the first substrate interconnection pattern 120 in an underlying interconnection layer. Alternatively, the via portion may extend from the bottom surface of the first substrate interconnection pattern 120 to penetrate the lowermost one of the first substrate insulating patterns 110 and may be coupled to top surfaces of the outer pads 130. An upper portion of the first substrate interconnection pattern 120, which is placed on the first substrate insulating pattern 110, may be a head portion, which is used for a horizontal interconnection or as a pad, and the via portion of the first substrate interconnection patterns 120 may be a tail portion, also described as a through portion. The first substrate interconnection patterns 120 may have a shape of letter ‘T’.

Although not shown, a barrier layer may be interposed between the first substrate insulating pattern 110 and the first substrate interconnection patterns 120. The barrier layer may be provided to enclose the head and tail portions of the first substrate interconnection patterns 120. A thickness of a gap region between the first substrate interconnection patterns 120 and the first substrate insulating pattern 110 (e.g., a thickness of the barrier layer) may be in a range from 50 Å to 1000 Å. The barrier layer may be formed of or include at least one of titanium (Ti), tantalum (Ta), titanium nitride (TiN), or tantalum nitride (TaN).

The outer pads 130 may be provided on a bottom surface of the lowermost one of the first substrate interconnection layers. The outer pads 130 may be electrically connected to the first substrate interconnection pattern 120. The outer pads 130 may be coupled to outer terminals 150, which will be described below. The outer pads 130 may include a conductive material. For example, the outer pads 130 may be formed of or include at least one of metallic materials (e.g., copper (Cu)).

A substrate protection layer 140 may be provided. The substrate protection layer 140 may be provided to cover a bottom surface of the lowermost one of the first substrate interconnection layers and expose the outer pads 130. The outer terminals 150 may be provided on exposed bottom surfaces of the outer pads 130. The substrate protection layer 140 may be formed of or include at least one of insulating polymers or photoimageable polymers (e.g., photoimageable dielectric (PID) materials).

The outer terminals 150, also described as external connection terminals for connecting the package to an external device, may include solder balls or solder bumps, and the semiconductor package may be classified into a ball grid array (BGA) package, a fine ball-grid array (FBGA) package, or a land grid array (LGA) package, depending on the kind and arrangement of the outer terminals 150.

The first redistribution substrate 100 may be provided to have the afore-described structure. However, the inventive concept is not limited to this example. The first redistribution substrate 100 may be a printed circuit board (PCB). For example, the first redistribution substrate 100 may include a core layer and peripheral portions, which are provided on and under the core layer and are used for interconnection.

The first semiconductor chip 200 may be disposed on the first redistribution substrate 100. When viewed in a plan view, the first semiconductor chip 200 may be disposed on a center region of the first redistribution substrate 100. The first semiconductor chip 200 may be a logic chip. In an embodiment, the first semiconductor chip 200 may be a memory chip (e.g., DRAM, SRAM, MRAM, or FLASH memory chip). The first semiconductor chip 200 may have a front surface and a rear surface. Hereinafter, in the present specification, the front surface may be a surface of a semiconductor chip, which is called an active surface, and on which integrated devices or pads are formed, and the rear surface may be another surface of the semiconductor chip that is opposite to the front surface. The first semiconductor chip 200 may be disposed such that the front surface thereof faces the first redistribution substrate 100. That is, the first semiconductor chip 200 may be disposed on the first redistribution substrate 100 in a face-down manner. The first semiconductor chip 200 may include a first base layer 210, and a first circuit layer 220, which is provided on the front surface of the first base layer 210.

The first base layer 210 may be formed of or include silicon (Si). An integrated device or an integrated circuit may be formed in a lower portion of the first base layer 210.

The first circuit layer 220 may be provided on a bottom surface of the first base layer 210. The first circuit layer 220 may be electrically connected to the integrated device or the integrated circuit, which is formed in the first base layer 210. For example, the first circuit layer 220 may have a first insulating pattern 222 and a first circuit pattern 224, which is provided in the first insulating pattern 222, and the first circuit pattern 224 may be coupled to the integrated device or the integrated circuit, which is formed in the first base layer 210. A portion of the first circuit pattern 224 may be exposed to the outside of the first circuit layer 220 near a bottom surface of the first circuit layer 220, and the exposed portion of the first circuit pattern 224 may correspond to the pad of the first semiconductor chip 200. A bottom surface of the first semiconductor chip 200, on which the first circuit layer 220 is provided, may be an active surface of the first semiconductor chip 200. The various pads, as described herein, may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected) to promote connection to a further terminal, such as a bump or solder ball, and/or an external wiring.

First chip connection terminals 202 may be provided on the bottom surface of the first semiconductor chip 200. The first chip connection terminals 202 may be electrically connected to the first circuit layer 220. For example, the first chip connection terminal 202 may be coupled to an exposed portion of the first circuit pattern 224. The first chip connection terminals 202 may be electrically connected to an input/output circuit (e.g., the logic or memory circuit), a power circuit, or a ground circuit of the first semiconductor chip 200. In an embodiment, the first chip connection terminals 202 may include solder balls, as shown in FIG. 1. Alternatively, the first chip connection terminals 202 may include solder bumps. In this case, the solder bump may be formed of or include at least one of metallic materials (e.g., copper (Cu)). The following description will be given based on the embodiment of FIG. 1.

The first semiconductor chip 200 may be mounted on the first redistribution substrate 100. For example, the first semiconductor chip 200 may be disposed such that the first circuit layer 220 faces a top surface of the first redistribution substrate 100. The first semiconductor chip 200 may be electrically connected to the first redistribution substrate 100 through the first chip connection terminals 202. The first chip connection terminals 202 may be provided between the first substrate pads 122 of the first redistribution substrate 100 and the first circuit layer 220 of the first semiconductor chip 200. Since the first semiconductor chip 200 is mounted on the first redistribution substrate 100 using the first chip connection terminals 202, the bottom surface of the first semiconductor chip 200 may be spaced apart from the first redistribution substrate 100. For example, the bottom surface of the first semiconductor chip 200 may be spaced apart from the top surface of the first redistribution substrate 100.

Although not shown, an under-fill layer, formed of an insulating material, may be provided between the first semiconductor chip 200 and the first redistribution substrate 100. The under-fill layer may fill a space between the first semiconductor chip 200 and the first redistribution substrate 100 and may enclose the first chip connection terminals 202.

A mold layer 300 may be provided on the first redistribution substrate 100. The mold layer 300 may cover the top surface of the first redistribution substrate 100. The mold layer 300 may enclose the first semiconductor chip 200, when viewed in a plan view. The mold layer 300 may be provided to cover top and side surfaces of the first semiconductor chip 200. A top surface of the mold layer 300 may be located at a level that is higher than the top surface of the first semiconductor chip 200. Here, the top surface of the first semiconductor chip 200 may correspond to a top surface of the first base layer 210 of the first semiconductor chip 200. The top surface of the first semiconductor chip 200 may be closer to the first redistribution substrate 100 than the top surface of the mold layer 300 is to the first redistribution substrate 100. For example, the first semiconductor chip 200 may be buried in the mold layer 300. FIG. 1 illustrates an example, in which the top surface of the mold layer 300 is located at a level different from the top surface of the first semiconductor chip 200, but the inventive concept is not limited to this example. In another embodiment, the top surface of the mold layer 300 may be located at the same level as the top surface of the first semiconductor chip 200. That is, the top surface of the mold layer 300 may be coplanar with the top surface of the first semiconductor chip 200. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. The following description will be given based on the embodiment of FIG. 1. If the under-fill layer is not provided, the mold layer 300 may be provided to fill the space between the first semiconductor chip 200 and the first redistribution substrate 100 and may enclose the first chip connection terminals 202. The mold layer 300 may be formed of or include an insulating material (e.g., epoxy molding compound (EMC)).

At least one conductive post 350 may be provided on the first redistribution substrate 100. The conductive posts 350 may be disposed at a side of the first semiconductor chip 200. The conductive posts 350 may vertically penetrate the mold layer 300. An end portion of the conductive post 350 may extend toward the first redistribution substrate 100 and may be coupled to the second substrate pad 124 of the first substrate interconnection pattern 120 of the first redistribution substrate 100. An opposite end portion of the conductive post 350 may extend toward the top surface of the mold layer 300. The conductive posts 350 may be exposed to the outside of the mold layer 300 at or near the top surface of the mold layer 300. Top surfaces of the conductive posts 350 may be coplanar with the top surface of the mold layer 300. An aspect ratio (e.g., of height to width) of each of the conductive posts 350 may be in a range from 2 to 10. Each of the plurality of conductive posts 350 may have the same aspect ratio as the other conductive posts 350. The conductive posts 350 may be formed of or include copper (Cu).

As shown in FIG. 2, each of the conductive posts 350 may include a first post 352 and a second post 354 on the first post 352, also described as a first post portion 352 and a second post portion 354.

Each first post 352 may be coupled to one of the second substrate pads 124 of the first substrate interconnection pattern 120 of the first redistribution substrate 100, to contact the respective second substrate pad 124. The first post 352 may be shaped like a pillar that extends in a direction perpendicular to the top surface of the first redistribution substrate 100. As an example, the first post 352 may have a circular pillar shape. However, the first post 352 may be provided to have a small aspect ratio. For example, the first post 352 may be shaped like a thin circular plate. The first post 352 may be in contact with a top surface of one of the second substrate pads 124. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

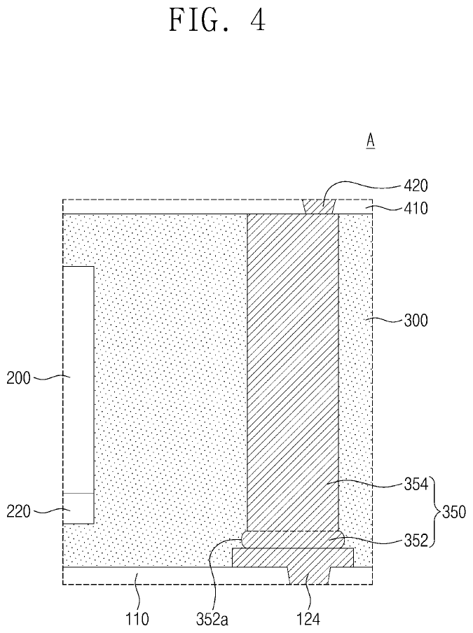

In an embodiment, the first post 352 may have a first width W1 that is substantially constant, regardless of a distance from the first redistribution substrate 100. For example, as shown in FIG. 2, an outer circumference surface 352a of the first post 352 may be flat, when viewed in a sectional view. Here, the outer circumference surface 352a of the first post 352 may be perpendicular to the top surfaces of the second substrate pads 124. That is, the first post 352 may have a rectangular cross-section. In another embodiment, the first width W1 of the first post 352 may decrease as a distance from the top surfaces of the second substrate pads 124 increases. In such an example, as shown in FIG. 3, the outer circumference surface 352a of the first post 352 may be flat, when viewed in a sectional view. Here, the outer circumference surface 352a of the first post 352 may be inclined at an angle to the top surfaces of the second substrate pads 124. That is, the first post 352 may have a trapezoidal cross-section. In still other embodiment, the first width W1 of the first post 352 may decrease as a distance from a vertical midpoint to the top or bottom surface of the first post 352 decreases. For example, as shown in FIG. 4, the outer circumference surface 352a of the first post 352 may be convex, when viewed in a cross-sectional view. The description that follows will be given based on the embodiment of FIG. 2.

The second post 354 may be connected to the first post 352. The second post 354 may be shaped like a pillar that is elongated (e.g., extends lengthwise) in a direction perpendicular to the top surface of the first redistribution substrate 100. An item, layer, or portion of an item or layer described as extending “lengthwise” in a particular direction has a length in the particular direction and a width perpendicular to that direction, where the length is greater than the width. A top surface of the second post 354 may be coplanar with the top surface of the mold layer 300. The second post 354 may have a second width W2 that is substantially constant along a vertical direction, regardless of a distance from the first redistribution substrate 100. The second width W2, which may be a maximum width, of the second post 354 may be smaller than the first width W1 of the first post 352, and in particular smaller than a maximum width W1 of the first post 352. For example, a planar area of the second post 354 (from a plan view) may be smaller than a planar area of the first post 352 (from a plan view), and when viewed in a plan view, the second post 354 may be placed within the first post 352. When viewed in a plan view, the second post 354 may be spaced apart from the outer circumference surface 352a of the first post 352 in a direction toward an inner portion of the first post 352. A first thickness T1 of the first post 352 may be smaller than a second thickness T2 of the second post 354. For example, the first thickness T1 of the first post 352 may be in a range from 0.1 μm to 10 μm. The second thickness T2 of the second post 354 may be in range from 250 μm to 500 μm. The second thickness T2 may be, for example in a range from 1/500 to 1/5000 the first thickness T1.

For the sake of clarity in the description, the first and second posts 352 and 354 have been described as two distinct posts within the conductive post 350; however, it should be understood that the first and second posts 352 and 354 may not necessarily be separate elements from one another. For example, the first and second posts 352 and 354 may be integrally formed with each other, thereby forming a single object. That is, the first and second posts 352 and 354 may be formed of or include the same material, and there may be no interface between the first and second posts 352 and 354. Therefore, the first and second posts 352 and 354 can be considered as two portions of the conductive post 350, which have different widths from each other but do not have any discernible interface that might be present when formed of different materials.

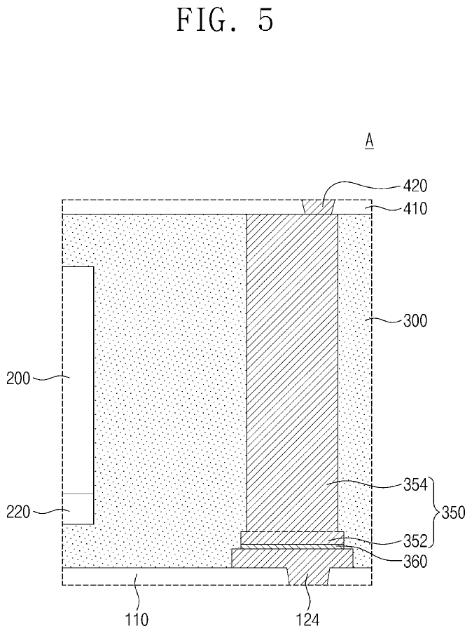

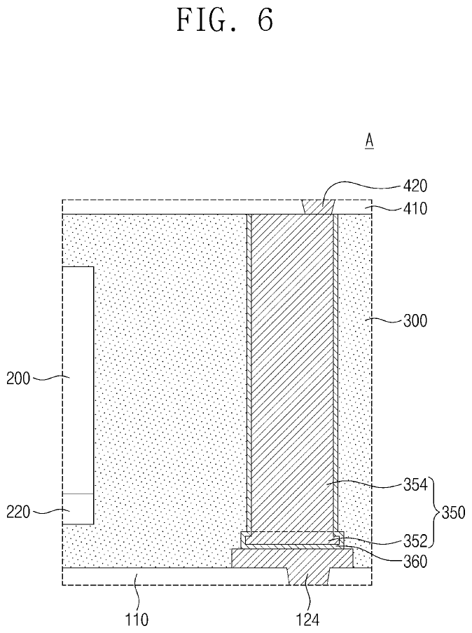

In another embodiment, a plurality of seed/barrier layers 360 may be interposed between the second substrate pads 124 and the conductive posts 350. As shown in FIG. 5, each of the seed/barrier layers 360 may cover a bottom surface of the first post 352 constituting a corresponding one of the conductive posts 350. The seed/barrier layers 360 may conformally cover the bottom surfaces of the first posts 352. The seed/barrier layers 360 may be provided to expose the side surfaces of the conductive posts 350 (i.e., the side surfaces of the first and second posts 352 and 354). Alternatively, as shown in FIG. 6, each of the seed/barrier layers 360 may be provided to cover bottom and side surfaces of a corresponding one of the conductive posts 350. The seed/barrier layers 360 may conformally cover the bottom and side surfaces of the conductive posts 350. For example, the seed/barrier layers 360 may conformally cover the bottom and side surfaces of the first post 352, a portion of the top surface of the first post 352, and the side surface of the second post 354. A thickness of a gap region between the second substrate pads 124 and the conductive posts 350 (i.e., a thickness of the seed/barrier layers 360) may be in a range from 50 Å to 1000 Å. In the case where the seed/barrier layers 360 is used as a seed layer, the seed/barrier layers 360 may be formed of or include at least one of metallic materials, such as gold (Au). In the case where the seed/barrier layers 360 is used as a barrier layer, the seed/barrier layers 360 may be formed of or include at least one of metallic materials, such as titanium (Ti) and tantalum (Ta), or metal nitride materials, such as titanium nitride (TiN) and tantalum nitride (TaN).

Referring further to FIGS. 1 and 2, a second redistribution substrate 400 may be provided on the mold layer 300 and the first semiconductor chip 200. The second redistribution substrate 400 may contact the top surface of the mold layer 300. In the case where the top surface of the first semiconductor chip 200 is exposed to the outside of the mold layer 300 near the top surface of the mold layer 300, the second redistribution substrate 400 may contact the top surface of the mold layer 300 and the top surface of the first semiconductor chip 200.

The second redistribution substrate 400 may include at least two second substrate interconnection layers, which are vertically stacked. Each of the second substrate interconnection layers may include a second substrate insulating pattern 410 and a second substrate interconnection pattern 420 in the second substrate insulating pattern 410. In the case where the second substrate interconnection layers are provided, the second substrate interconnection pattern 420 of each second substrate interconnection layer may be electrically connected to the second substrate interconnection pattern 420 of another second substrate interconnection layer adjacent thereto.

The second substrate insulating pattern 410 may be formed of or include at least one of insulating polymers or photoimageable dielectric (PID) materials. For example, the photoimageable dielectric materials may be at least one of photoimageable polyimide (PI), polybenzoxazole (PBO), phenol-based polymers, or benzocyclobutene-based polymers. Alternatively, the second substrate insulating pattern 410 may include a different insulating material. For example, the second substrate insulating pattern 410 may be formed of or include at least one of silicon oxide (SiO), silicon nitride (SiN), silicon oxynitride (SiON), or insulating polymers.

The second substrate interconnection pattern 420 may be provided on the second substrate insulating pattern 410. On the second substrate insulating pattern 410, the second substrate interconnection pattern 420 may extend horizontally. The second substrate interconnection pattern 420 may be provided on a top surface of the second substrate insulating pattern 410. The second substrate interconnection pattern 420 may extend above the top surface of the second substrate insulating pattern 410. The second substrate interconnection pattern 420 on the second substrate insulating pattern 410 may be covered with another one of the second substrate insulating patterns 410 thereon. The second substrate interconnection pattern 420, which is provided on the uppermost one of the second substrate interconnection layers, may be used as redistribution pads, on which an external element or an external electronic device is mounted. As described above, the second substrate interconnection pattern 420 may also be used as the pad or wire portion of the second substrate interconnection layer. That is, the second substrate interconnection pattern 420 may be an element, which is a part of the second substrate interconnection layer and is used for a horizontal redistribution. For example, the second substrate interconnection pattern 420 may connect the redistribution pads to the conductive posts 350, as shown in FIG. 1. The conductive post 350 may correspond to a vertical connection portion electrically connecting the first redistribution substrate 100 to the second redistribution substrate 400. FIG. 1 illustrates an example of the electric connection structure of the second substrate interconnection pattern 420, and the shape and disposition of the second substrate interconnection pattern 420 is not limited to the example of FIG. 1. The second substrate interconnection pattern 420 may include a conductive material. For example, the second substrate interconnection pattern 420 may be formed of or include copper (Cu).

The second substrate interconnection pattern 420 may have a damascene structure. In this case, the second substrate interconnection pattern 420 may include a head portion and a tail portion, which are connected to each other to form a single object. The head and tail portions of the second substrate interconnection pattern 420 may be provided to have a ‘T’-shaped section.

The head portion of the second substrate interconnection pattern 420 may be a wire portion or a pad portion, which is used for a horizontal extension of an interconnection structure in the second redistribution substrate 400. The head portion may be provided on the top surface of the second substrate insulating pattern 410. For example, the head portion may extend horizontally above the top surface of the second substrate insulating pattern 410.

The tail portion of the second substrate interconnection pattern 420 may be a via portion, which is used for a vertical connection of an interconnection structure in the second redistribution substrate 400. The tail portion may be coupled to another second substrate interconnection layer thereunder. For example, the tail portion of the second substrate interconnection pattern 420 may extend vertically from the bottom surface of the head portion to penetrate the second substrate insulating pattern 410 and may be coupled to the head portion of the second substrate interconnection pattern 420, which is provided in another second substrate interconnection layer thereunder. The tail portion of the second substrate interconnection pattern 420 in the lowermost one of the second substrate interconnection layers may penetrate the second substrate insulating pattern 410 and may be exposed to the outside of the second redistribution substrate 400 near the bottom surface of the second redistribution substrate 400. Here, the tail portion of the second substrate interconnection pattern 420 in the lowermost one of the second substrate interconnection layers may be placed on the mold layer 300. The tail portion of the second substrate interconnection pattern 420 of the lowermost one of the second substrate interconnection layers may be coupled to and may contact the conductive posts 350.

A second semiconductor chip 500 may be disposed on the second redistribution substrate 400. When viewed in a plan view, the second semiconductor chip 500 may be disposed on a center region of the second redistribution substrate 400. The second semiconductor chip 500 may be a logic chip or a memory chip. The second semiconductor chip 500 may have a front surface and a rear surface. The second semiconductor chip 500 may be disposed such that the front surface thereof faces the second redistribution substrate 400. In other words, the second semiconductor chip 500 may be disposed on the second redistribution substrate 400 in a face down manner. The second semiconductor chip 500 may include a second base layer 510 and a second circuit layer 520, which is provided on the front surface of the second base layer 510.

The second base layer 510 may be formed of or include silicon (Si). An integrated device or an integrated circuit may be formed in a lower portion of the second base layer 510.

The second circuit layer 520 may be provided on a bottom surface of the second base layer 510. The second circuit layer 520 may be electrically connected to the integrated device or the integrated circuit, which is formed in the second base layer 510. For example, the second circuit layer 520 may have a second insulating pattern 522 and a second circuit pattern 524, which is provided in the second insulating pattern 522, and the second circuit pattern 524 may be coupled to an integrated device or integrated circuits, which are formed in the second base layer 510. A portion of the second circuit pattern 524 may be exposed to the outside of the second circuit layer 520 near a bottom surface of the second circuit layer 520, and the exposed portion of the second circuit pattern 524 may serve as a pad of the second semiconductor chip 500. A bottom surface of the second semiconductor chip 500, on which the second circuit layer 520 is provided, may be an active surface of the second semiconductor chip 500.

Second chip connection terminals 502 may be provided on the bottom surface of the second semiconductor chip 500. The second chip connection terminals 502 may be electrically connected to the second circuit layer 520. For example, each of the second chip connection terminals 502 may be coupled to the exposed portion of the second circuit pattern 524. The second chip connection terminals 502 may be electrically connected to an input/output circuit (e.g., the logic or memory circuit), a power circuit, or a ground circuit of the second semiconductor chip 500. The second chip connection terminals 502 may include solder balls, as shown in FIG. 1. Alternatively, the second chip connection terminals 502 may include solder bumps. In this case, the solder bump may be formed of or include at least one of metallic materials (e.g., copper (Cu)).

The second semiconductor chip 500 may be mounted on the second redistribution substrate 400. For example, the second circuit layer 520 of the second semiconductor chip 500 may be provided to face a top surface of the second redistribution substrate 400. The second semiconductor chip 500 may be electrically connected to the second redistribution substrate 400 through the second chip connection terminals 502. The second chip connection terminals 502 may be provided between the second substrate interconnection patterns 420, which are provided in the uppermost one of the second substrate interconnection layers of the second redistribution substrate 400, and the second circuit layer 520, which is provided in the second semiconductor chip 500. Since the second semiconductor chip 500 is mounted on the second redistribution substrate 400 using the second chip connection terminals 502, the bottom surface of the second semiconductor chip 500 may be spaced apart from the second redistribution substrate 400. For example, the bottom surface of the second semiconductor chip 500 may be spaced apart from the top surface of the second redistribution substrate 400.

Although not shown, an under-fill layer may be provided between the second semiconductor chip 500 and the second redistribution substrate 400. The under-fill layer may be provided to fill a space between the second semiconductor chip 500 and the second redistribution substrate 400 and may enclose the second chip connection terminals 502.

For concise description, an element previously described with reference to FIGS. 1 to 6 may be identified by the same reference number without repeating an overlapping description thereof. That is, technical features, which are different from those in the embodiments of FIGS. 1 to 6, will be mainly described below.

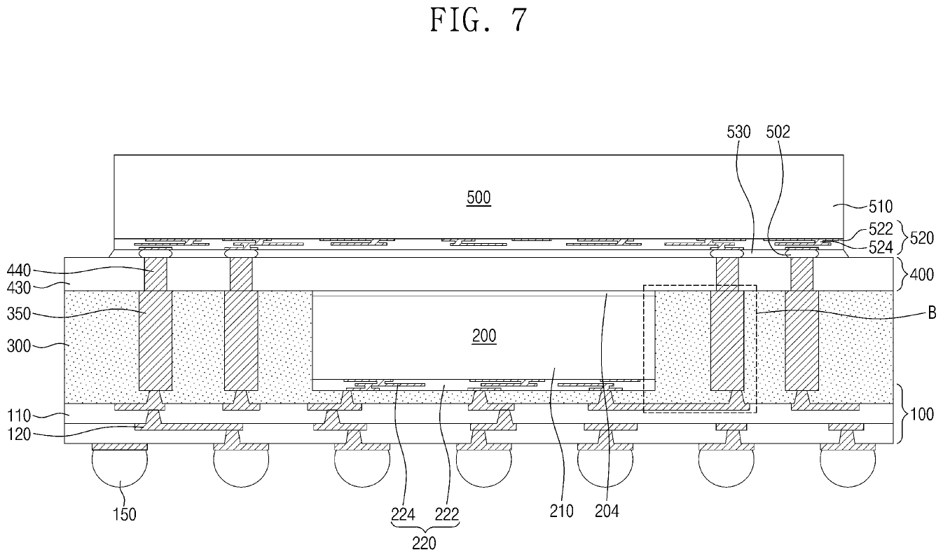

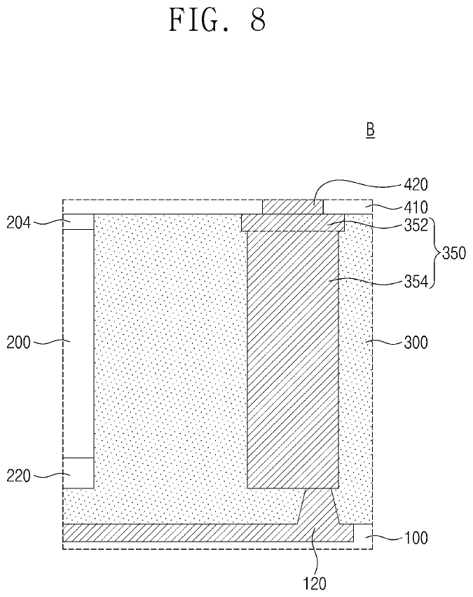

FIG. 7 is a sectional view illustrating a semiconductor package according to an embodiment of the inventive concept. FIGS. 8 to 12 are enlarged sectional views illustrating a portion ‘B’ of FIG. 7.

FIGS. 1 to 6 illustrate an example, in which the first semiconductor chip 200 is mounted on the first redistribution substrate 100 using the first chip connection terminals 202, but the inventive concept is not limited to this example.

Referring to FIGS. 7 and 8, the first redistribution substrate 100 may include at least two first substrate interconnection layers, which are vertically stacked. Each of the first substrate interconnection layers may include the first substrate insulating pattern 110 and the first substrate interconnection pattern 120 in the first substrate insulating pattern 110.

The first substrate interconnection pattern 120 may be provided under the first substrate insulating pattern 110. Under the first substrate insulating pattern 110, the first substrate interconnection pattern 120 may be formed to extend horizontally. The first substrate interconnection pattern 120 may be provided under a bottom surface of the first substrate insulating pattern 110. The first substrate interconnection pattern 120 may be exposed to the outside of the first substrate insulating pattern 110 near the bottom surface of the first substrate insulating pattern 110. The first substrate interconnection pattern 120 under the first substrate insulating pattern 110 may be covered with another one of the first substrate insulating patterns 110 thereunder. The first substrate interconnection pattern 120, which is provided on the lowermost one of the first substrate interconnection layers, may be used as the outer pads 130. For example, the outer terminals 150 may be coupled to the first substrate interconnection pattern 120, which is provided on the lowermost one of the first substrate interconnection layers.

The first substrate interconnection pattern 120 may have a damascene structure. For example, the first substrate interconnection pattern 120 may include via portions that is extended upward from a top surface thereof. The via portions may be used to vertically connect the first substrate interconnection patterns 120, which are respectively provided in adjacent ones of the interconnection layers, to each other. Alternatively, the via portions may be used to connect the first substrate interconnection pattern 120 in the uppermost one of the interconnection layers to the first semiconductor chip 200 and the conductive posts 350. For example, the via portion may extend from the top surface of the first substrate interconnection pattern 120 to penetrate the first substrate insulating pattern 110 and may be coupled to a bottom surface of the first substrate interconnection pattern 120 in another interconnection layer thereon. In an embodiment, the via portion may be extended from the top surface of the first substrate interconnection pattern 120 to penetrate the uppermost one of the first substrate insulating patterns 110 and may be exposed to the outside of the first redistribution substrate 100 near the top surface of the first redistribution substrate 100. A lower portion of the first substrate interconnection pattern 120, which is placed under the bottom surface of the first substrate insulating pattern 110, may be a head portion, which is used for a horizontal interconnection or as a pad, and the via portion of the first substrate interconnection patterns 120 may be a tail portion. The first substrate interconnection patterns 120 may have an inverted shape of letter ‘T’.

The first semiconductor chip 200 and at least one conductive post 350 may be disposed on the first redistribution substrate 100. The first semiconductor chip 200 may further include an adhesive layer 204, which is provided on a top surface of the first base layer 210. The first semiconductor chip 200 and the conductive posts 350 may be spaced apart from the first redistribution substrate 100. For example, the bottom surface of the first circuit layer 220 of the first semiconductor chip 200 and the bottom surfaces of the conductive posts 350 may be spaced apart from the top surface of the first redistribution substrate 100. It should be noted that spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

As shown in FIG. 8, each of the conductive posts 350 may include the second post 354 and the first post 352 on the second post 354. The conductive posts 350 in the embodiment of FIGS. 7 and 8 may have a structure that is obtained by inverting the conductive posts 350 in the embodiment of FIGS. 1 and 2. That is, the first and second posts 352 and 354 in the embodiment of FIGS. 7 and 8 may have shapes and features corresponding to the first and second posts 352 and 354 in the embodiment of FIGS. 1 and 2.

The second post 354 may be shaped like a pillar that is elongated in a direction perpendicular to the top surface of the first redistribution substrate 100. The second post 354 may have a substantially constant width, regardless of a distance from the first redistribution substrate 100. The second post 354 may be coupled to the first substrate interconnection pattern 120 of the first redistribution substrate 100. For example, the via portion of the first substrate interconnection pattern 120 in the uppermost one of the interconnection layers may penetrate the mold layer 300 and may be coupled to a chip pad of the first semiconductor chip 200 and the second post 354 of the conductive post 350.

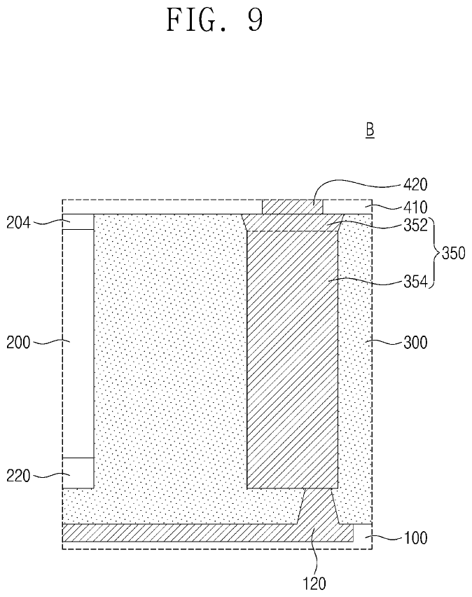

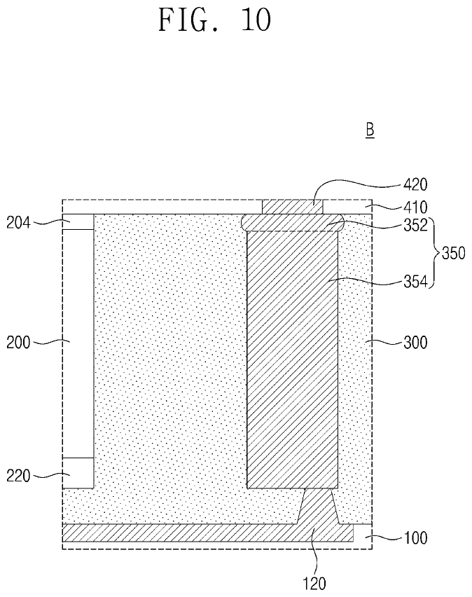

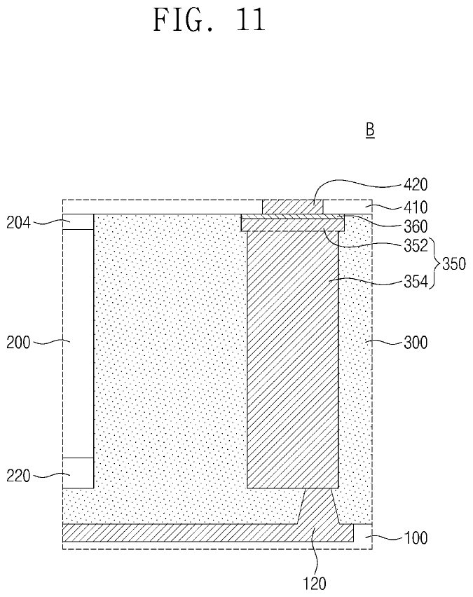

The first post 352 may be connected to a top portion of the second post 354. The first post 352 may be shaped like a pillar that extends in a direction perpendicular to the top surface of the first redistribution substrate 100. As an example, the first post 352 may have a shape of a circular pillar. However, the first post 352 may have a small aspect ratio. For example, the first post 352 may be shaped like a thin circular plate. A top surface of the first post 352 may be coplanar with the top surface of the mold layer 300. The first post 352 may have a substantially constant width, regardless of a distance from the first redistribution substrate 100. For example, an outer circumference surface of the first post 352 may be perpendicular to the top surface of the mold layer 300. In another embodiment, the width of the first post 352 may decrease as a distance from the top surface of the mold layer 300 increases. As shown in FIG. 9, the outer circumference surface of the first post 352 may be inclined at an angle to the top surface of the mold layer 300. In still other embodiment, the width of the first post 352 may decrease as a distance to the top or bottom surface of the first post 352 decreases. For example, as shown in FIG. 10, the outer circumference surface of the first post 352 may be convex, when viewed in a sectional view. The description that follows will be given based on the embodiment of FIG. 8. The width of the first post 352 may be larger than the width of the second post 354. For example, a planar area of the first post 352 may be larger than a planar area of the second post 354, and when viewed in a plan view, the second post 354 may be placed within the second post 354. When viewed in a plan view, the second post 354 may be spaced apart from the outer circumference surface of the first post 352 in a direction toward an inner portion of the first post 352. A thickness of the first post 352 may be smaller than a thickness of the second post 354. For example, the thickness of the first post 352 may be in a range from 0.1 μm to 10 μm.

Referring further to FIGS. 7 and 8, the mold layer 300 may be provided on the first redistribution substrate 100. The mold layer 300 may enclose the first semiconductor chip 200 and the conductive posts 350, when viewed in a plan view. The mold layer 300 may be provided to expose the top surface of the first semiconductor chip 200 and the top surfaces of the conductive posts 350. The top surface of the mold layer 300 may be coplanar with the top surface of the first semiconductor chip 200 and the top surfaces of the conductive posts 350. The mold layer 300 may cover the bottom surface of the first semiconductor chip 200 and the bottom surfaces of the conductive posts 350. A space between the first redistribution substrate 100 and the first semiconductor chip 200 and a space between the first redistribution substrate 100 and the conductive posts 350 may be filled with the mold layer 300.

The second redistribution substrate 400 may be disposed on the mold layer 300 and the first semiconductor chip 200. The second redistribution substrate 400 may be a silicon interposer substrate. For example, the second redistribution substrate 400 may include a base layer 430 and a vertical connection portion 440.

The base layer 430 may be formed of or include silicon (Si). FIG. 7 illustrates an example in which the base layer 430 is composed of a single silicon substrate layer, but the inventive concept is not limited to this example. The base layer 430 may be composed of a plurality of silicon substrate layers which are stacked.

Each of the vertical connection portions 440 may include or be a through-silicon via (TSV) (generally described as a through-substrate via) vertically penetrating the base layer 430. The vertical connection portions 440, also described as through vias, may have top surfaces that are exposed to the outside of the base layer 430 near a top surface of the base layer 430. The vertical connection portions 440 may have bottom surfaces that are exposed to the outside of the base layer 430 near a bottom surface of the base layer 430. The vertical connection portions 440 may be connected to the conductive posts 350 at an interface between the second redistribution substrate 400 and the mold layer 300. For example, a bottom surface of each of the vertical connection portions 440 may be in contact with a top surface of one of the conductive posts 350. In the case where the base layer 430 includes a plurality of silicon substrate layers, each of the vertical connection portions 440 may include a plurality of layers, each of which vertically penetrates one of the silicon substrate layers, and the layers of the vertical connection portions 440 may be vertically connected to each other.

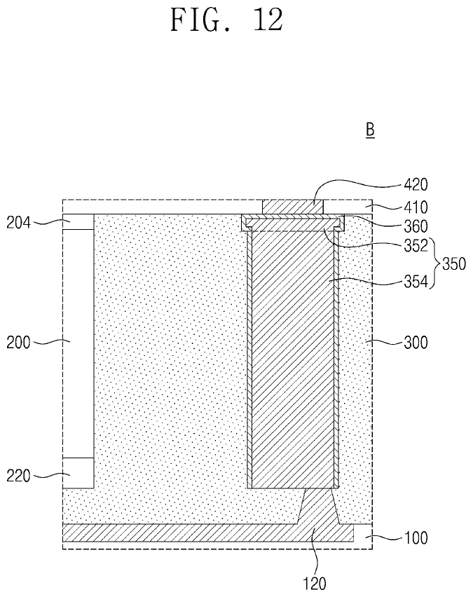

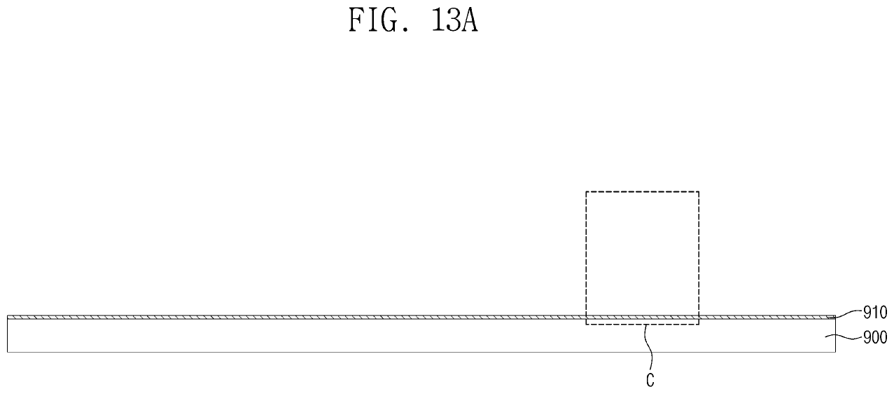

In another embodiment, a plurality of seed/barrier layers 360 may be interposed between the second redistribution substrate 400 and the conductive posts 350. As shown in FIG. 11, each of the seed/barrier layers 360 may cover a top surface of the first post 352 of one of the conductive posts 350. The seed/barrier layers 360 may conformally cover the top surface of the first post 352. The seed/barrier layers 360 may be provided to expose the side surfaces of the conductive posts 350 (i.e., the side surfaces of the first and second posts 352 and 354). Alternatively, as shown in FIG. 12, each of the seed/barrier layers 360 may conformally cover top and side surfaces of one of the conductive posts 350. For example, the seed/barrier layers 360 may conformally cover top and side surfaces of the first post 352, a portion of a bottom surface of the first post 352, and a side surface of the second post 354.

Referring further to FIGS. 7 and 8, the second semiconductor chip 500 may be disposed on the second redistribution substrate 400. The second semiconductor chip 500 may be mounted on the second redistribution substrate 400. The second chip connection terminals 502 may be provided between the vertical connection portions 440 of the second redistribution substrate 400 and the second circuit layer 520 of the second semiconductor chip 500.

An under-fill layer 530 may be provided between the second semiconductor chip 500 and the second redistribution substrate 400. The under-fill layer 530 may fill a space between the second semiconductor chip 500 and the second redistribution substrate 400 and may enclose the second chip connection terminals 502.

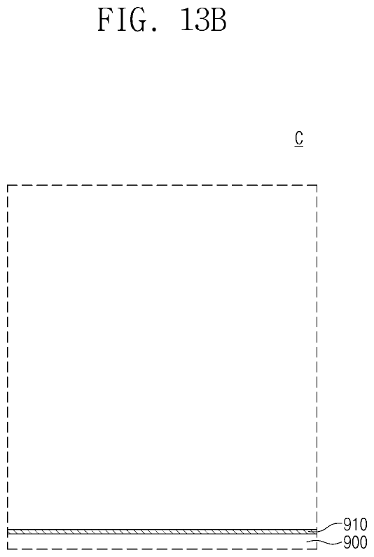

FIGS. 13A to 23A are sectional views illustrating a method of fabricating a semiconductor package, according to an embodiment of the inventive concept. FIGS. 13B to 23B are enlarged sectional views illustrating portions ‘C’ of FIGS. 13A to 23A.

Referring to FIGS. 13A and 13B, a carrier substrate 900 may be provided. The carrier substrate 900 may be an insulating substrate, which is formed of or includes glass or polymer, or a conductive substrate, which is formed of or includes a metallic material. Although not shown, an adhesive member may be provided on a top surface of the carrier substrate 900. In an embodiment, the adhesive member may include an adhesive tape.

A seed layer 910 may be formed on the carrier substrate 900. For example, the seed layer 910 may be formed by attaching a metal foil, which is formed of a metallic material, to the carrier substrate 900 or by depositing or plating the metallic material on the carrier substrate 900. The seed layer 910 may be formed to cover the entire top surface of the carrier substrate 900. A thickness of the seed layer 910 may be in a range from 1 μm to 5 μm. The metallic material may include or may be copper (Cu).

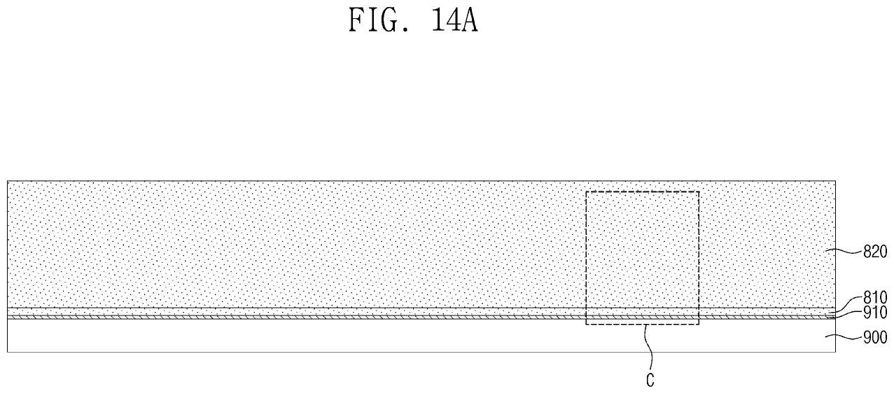

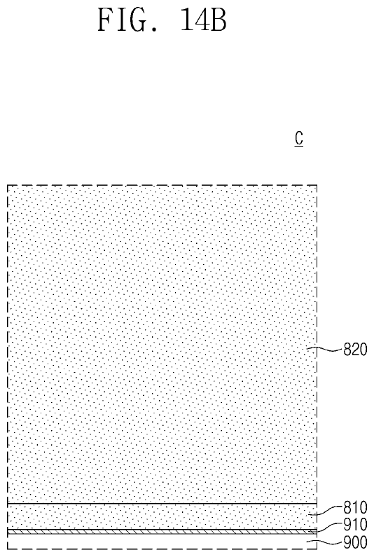

Referring to FIGS. 14A and 14B, a sacrificial layer 810 and a photoimageable layer 820 may be sequentially stacked on the seed layer 910. A thickness of the sacrificial layer 810 may be smaller than a thickness of the photoimageable layer 820. For example, the thickness of the sacrificial layer 810 may be in a range from 0.1 μm to 10 μm. The thickness of the photoimageable layer 820 may be in a range from 250 μm to 500 μm to be, for example, between 50 and 2500 times the thickness of the sacrificial layer 810. The sacrificial layer 810 and the photoimageable layer 820 may be formed of or include different materials from each other. For example, both of the sacrificial layer 810 and the photoimageable layer 820 may be formed of or include a photoimageable material. Here, the sacrificial layer 810 and the photoimageable layer 820 may be dissolved by the same dissolving solution but may have different dissolution rates from each other. For example, a dissolution rate of the sacrificial layer 810 by the dissolving solution may be faster than that of the photoimageable layer 820. As an example, the sacrificial layer 810 may be formed of or include at least one of acrylate-based polymers. Alternatively, the sacrificial layer 810 and the photoimageable layer 820 may be dissolved by the same dissolving solution, the sacrificial layer 810 may have thermal reactivity or optical reactivity, and the photoimageable layer 820 may not have thermal reactivity or optical reactivity. For example, the thermal reactivity may include a thermally decomposable property. For example, the optical reactivity may include a photolytic property or an optically foaming property. Alternatively, the sacrificial layer 810 and the photoimageable layer 820 may be dissolved using distinct dissolving solutions for each layer.

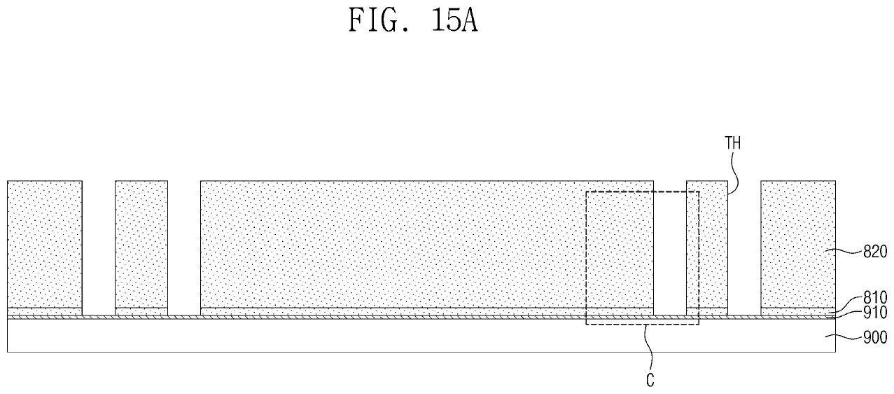

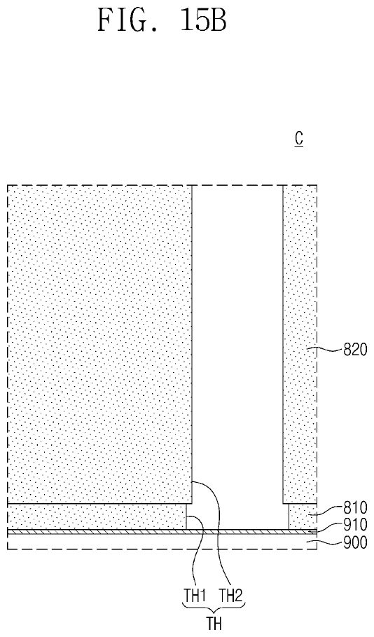

Referring to FIGS. 15A and 15B, penetration holes TH may be formed in the sacrificial layer 810 and the photoimageable layer 820. For example, the penetration holes TH may be formed by performing an exposure and developing process on the sacrificial layer 810 and the photoimageable layer 820. The penetration holes TH may be formed to vertically penetrate the sacrificial layer 810 and the photoimageable layer 820 and to expose a top surface of the seed layer 910. In one embodiment, since the sacrificial layer 810 and the photoimageable layer 820 include different materials from each other, a width of a first penetration hole TH1 in the sacrificial layer 810 may be different from a width of a second penetration hole TH2 in the photoimageable layer 820. For example, the width of the first penetration hole TH1 may be larger than the width of the second penetration hole TH2. A planar area of the first penetration hole TH1 may be larger than a planar area of the second penetration hole TH2, and the second penetration hole TH2 may be placed within the first penetration hole TH1, when viewed in a plan view. The first and second penetration holes TH1 and TH2 may be vertically connected to each other and may form a single penetration hole TH.

FIGS. 15A and 15B illustrate an example, in which an inner side surface of the first penetration hole TH1 is perpendicular to the top surface of the seed layer 910 and has a flat section, but the inventive concept is not limited to this example. For example, the inner side surface of the first penetration hole TH1 may be inclined at an angle to the top surface of the seed layer 910. For example, a width of the first penetration hole TH1 may decrease as a distance from the top surface of the seed layer 910 increases. In an embodiment, the width of the first penetration hole TH1 may decrease as a distance to the top surface of the seed layer 910 and the second penetration hole TH2 decreases. For example, the inner side surface of the first penetration hole TH1 may be concave, when viewed in a sectional view.

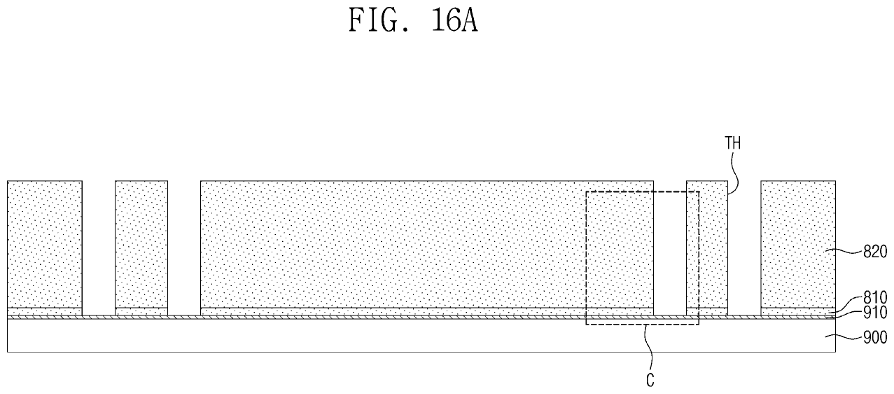

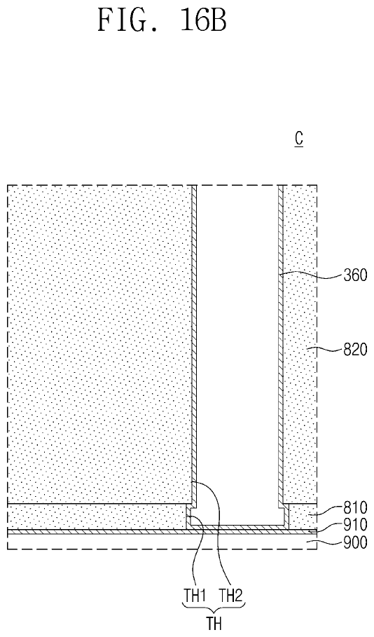

In another embodiment, referring to FIGS. 16A and 16B, the seed/barrier layer 360 may be formed in the penetration holes TH. For example, the seed/barrier layer 360 may be formed by depositing or coating a metal layer on inner side surfaces and bottom surfaces of the penetration holes TH and a top surface of the photoimageable layer 820. A thickness of the seed/barrier layer 360 may be in a range from 50 Å to 1000 Å. The seed/barrier layer 360 may be formed of or include at least one of metallic materials (e.g., gold (Au), titanium (Ti), and tantalum (Ta)) or metal nitride materials (e.g., titanium nitride (TiN) and tantalum nitride (TaN)). In an embodiment, the seed/barrier layer 360 may not be formed. The following description will be given, based on the embodiment of FIGS. 15A and 15B.

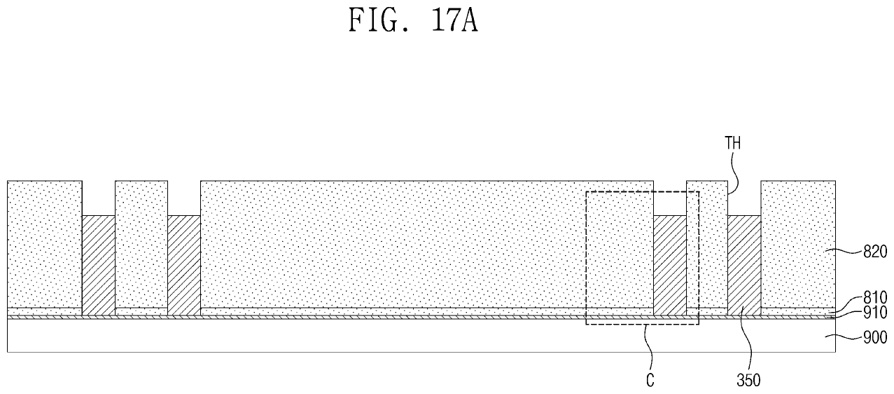

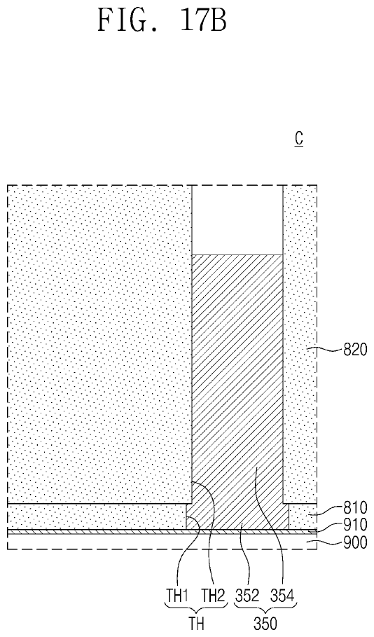

Referring to FIGS. 17A and 17B, the conductive posts 350 may be formed in the penetration holes TH. For example, a metallic material filling the penetration holes TH may be formed by a plating process, in which the seed layer 910 exposed through the penetration holes TH is used as a seed. The metallic material may be formed to fill the penetration holes TH and cover the top surface of the photoimageable layer 820. Thereafter, an etch-back process may be performed on the metallic material to form the conductive posts 350 in the penetration holes TH. In an embodiment, the etch-back process may be performed to remove the metallic material from a region on the photoimageable layer 820 and from upper portions of the penetration holes TH. Alternatively, the plating process may be performed such that a top surface of the metallic material is located within the penetration holes TH. The metallic material, which is placed in the penetration holes TH, may constitute the conductive posts 350. Owing the shapes of the penetration holes TH, each of the conductive posts 350 in the penetration holes TH may include the first post 352 and the second post 354, which are respectively formed in the first and second penetration holes TH1 and TH2. The first and second posts 352 and 354 may be substantially the same as or similar to those described with reference to FIGS. 1 to 6. For example, the first post 352 may have a width and a planar area that are larger than those of the second post 354. Since the first and second posts 352 and 354 are formed using a single plating process, the first and second posts 352 and 354 may form a single object without any interface therebetween.

In the case where, as shown in FIGS. 16A and 16B, the seed/barrier layer 360 is formed in the penetration holes TH, a plating process using the seed/barrier layer 360 as a seed may be performed. As a result of the plating process, a metallic material may be formed to fill the penetration holes TH and cover the top surface of the photoimageable layer 820, and then, a portion of the metallic material and a portion of the seed/barrier layer 360, which are placed on the top surface of the photoimageable layer 820, may be removed to form the conductive posts 350. In this case, the semiconductor package may be fabricated to have the structure described with reference to FIG. 6 or 12.

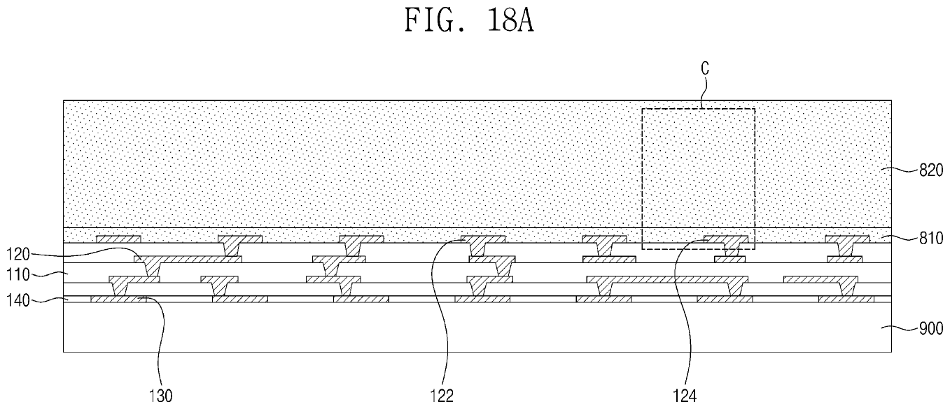

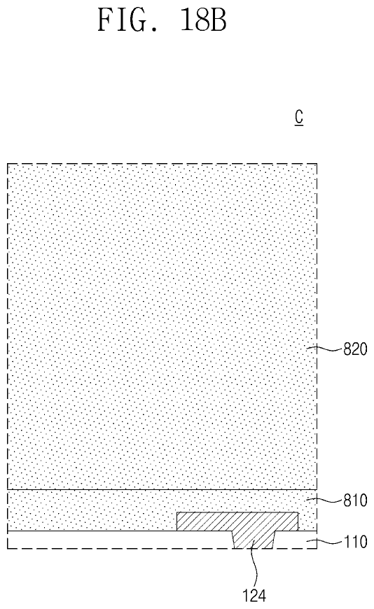

In another embodiment, the first redistribution substrate 100 may be formed, before the formation of the sacrificial layer 810 and the photoimageable layer 820. Referring to FIGS. 18A and 18B, the carrier substrate 900 may be provided.

The first redistribution substrate 100 may be formed on the carrier substrate 900. For example, the substrate protection layer 140 may be formed by depositing a photoimageable insulating layer on the carrier substrate 900. An exposure process may be performed on the substrate protection layer 140, and then, penetration holes may be formed by patterning the substrate protection layer 140. The outer pads 130 may be formed by filling the penetration holes of the substrate protection layer 140 with a conductive material. An insulating layer may be formed by depositing an insulating material on the substrate protection layer 140, and the first substrate insulating pattern 110 may be formed by patterning the insulating layer to expose the outer pads 130. Thereafter, a conductive layer may be formed on the first substrate insulating pattern 110 and may be patterned to form the first substrate interconnection pattern 120. As a result of the above process, a first substrate interconnection layer may be formed. The first redistribution substrate 100 may be formed by repeating the process of forming the first substrate interconnection layer several times. The first substrate interconnection patterns 120, which are provided in the uppermost one of the first substrate interconnection layers, may be used as the first substrate pads 122 and the second substrate pads 124.

The sacrificial layer 810 and the photoimageable layer 820 may be sequentially stacked on the first redistribution substrate 100. The sacrificial layer 810 and the photoimageable layer 820 may be substantially the same as or similar to those described with reference to FIGS. 14A and 14B in terms of their structure and formation method. The sacrificial layer 810 may be formed on the first redistribution substrate 100 to cover the first substrate pads 122 and the second substrate pads 124.

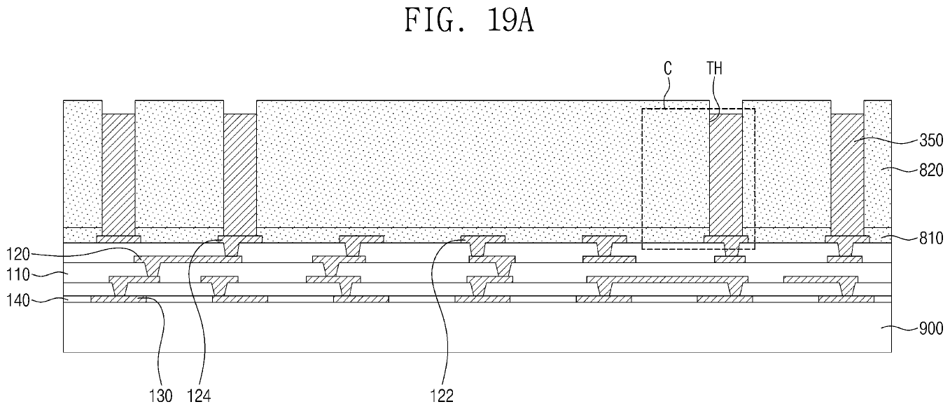

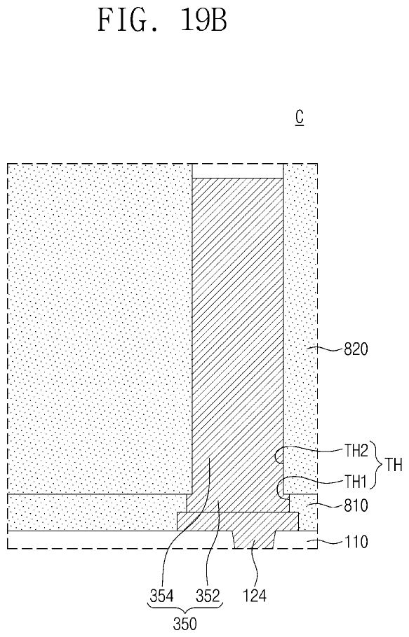

Referring to FIGS. 19A and 19B, the penetration holes TH may be formed in the sacrificial layer 810 and the photoimageable layer 820. For example, the penetration holes TH may be formed by performing an exposure and developing process on the sacrificial layer 810 and the photoimageable layer 820. The penetration holes TH may be formed to vertically penetrate the sacrificial layer 810 and the photoimageable layer 820 and expose the top surfaces of the second substrate pads 124 of the first redistribution substrate 100. The width of the first penetration hole TH1 may be larger than the width of the second penetration hole TH2.

The conductive posts 350 may be formed in the penetration holes TH. For example, the penetration holes TH may be filled with a metallic material by a plating process using the second substrate pads 124, which are exposed through the penetration holes TH, as a seed layer. Each of the conductive posts 350, which are respectively formed in the penetration holes TH, may have the first post 352 and the second post 354, which are formed in the first and second penetration holes TH1 and TH2. The first post 352 may have a width and a planar area that are larger than those of the second post 354. In this case, the semiconductor package may be fabricated to have the structure described with reference to FIGS. 1 to 6. The following description will be given, based on the embodiment of FIGS. 17A and 17B.

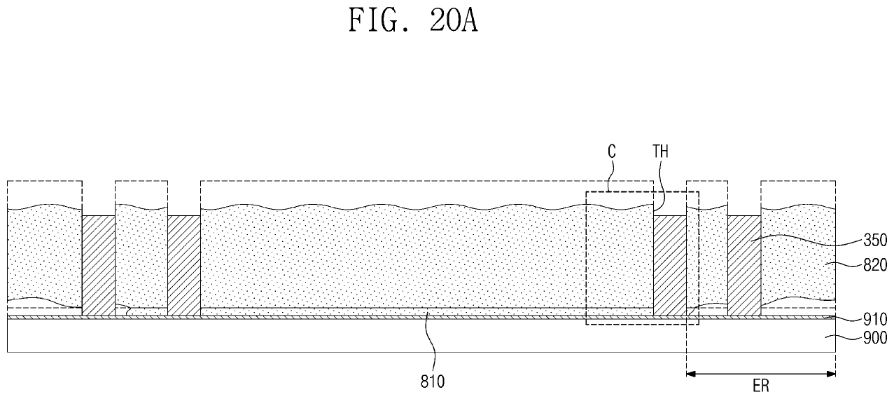

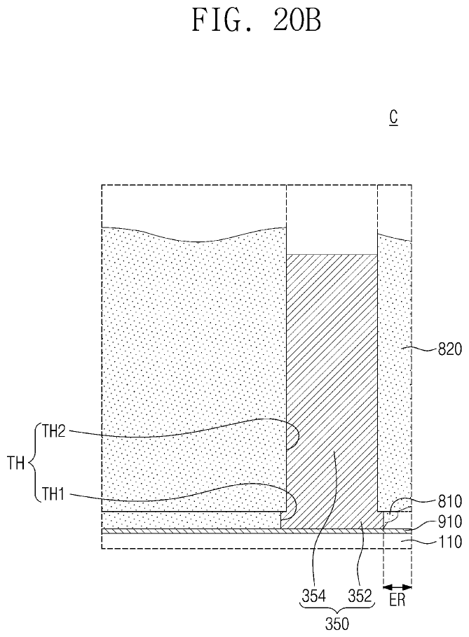

Referring to FIGS. 20A and 20B, a process may be performed to remove the sacrificial layer 810 and the photoimageable layer 820. For example, the process may include a strip process. The strip process may be a wet etching process. In more detail, dissolving solution may be used to dissolve the sacrificial layer 810 and the photoimageable layer 820. In an embodiment, the dissolving solution may contain tetramethylammonium hydroxide (TMAH). Here, the dissolving solution may dissolve the photoimageable layer 820 in a direction from the top surface of the photoimageable layer 820 toward an inner portion of the photoimageable layer 820. The dissolving solution may dissolve the sacrificial layer 810 and the photoimageable layer 820 in a direction from side surfaces of the sacrificial layer 810 and the photoimageable layer 820 toward inner portions of the sacrificial layer 810 and the photoimageable layer and 820. The process of removing the sacrificial layer 810 and the process of removing the photoimageable layer 820 may be performed at the same time. A dissolution rate of the sacrificial layer 810 may be faster than a dissolution rate of the photoimageable layer 820. Accordingly, the sacrificial layer 810 between the seed layer 910 and the photoimageable layer 820 may be dissolved at a relatively fast rate, and thus, the dissolving solution may be easily supplied into a region between the seed layer 910 and the photoimageable layer and 820. In a region ER formed between the seed layer 910 and the photoimageable layer 820 by the removal of the sacrificial layer 810, the dissolving solution may dissolve the photoimageable layer 820 in a direction from a bottom surface of the photoimageable layer 820 toward an inner portion of the photoimageable layer 820.

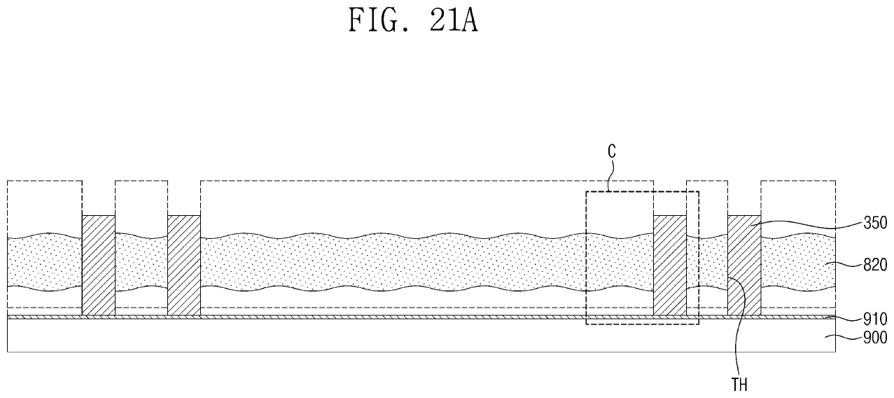

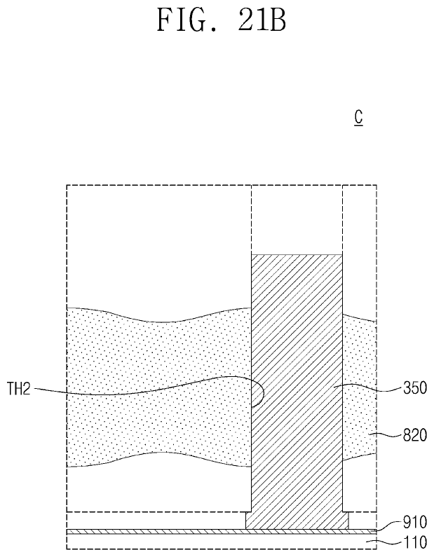

Referring to FIGS. 21A and 21B, the strip process may be further performed to entirely remove the sacrificial layer 810 using the dissolving solution. Thus, the entire top surface of the seed layer 910 and the entire bottom surface of the photoimageable layer 820 may be exposed. The dissolving solution may be more easily supplied into a space between the seed layer 910 and the photoimageable layer 820.

In some cases, a semiconductor package may require a conductive post having a large vertical length, and a thick photoimageable layer may be required to form such a conductive post. In this case, it may take a long time to remove the photoimageable layer. Furthermore, if the dissolving solution is provided to only a top surface of the photoimageable layer, a lower portion of the photoimageable layer located on a seed layer may not be removed and may be left as a residue.

According to an embodiment of the inventive concept, the sacrificial layer 810, which is in contact with the top surface of the seed layer 910, may be formed of a material that can be dissolved at a high dissolution rate by the dissolving solution. This may make it possible to easily remove the sacrificial layer 810 from the top surface of the seed layer 910. Furthermore, since the sacrificial layer 810 is removed before the removing of the photoimageable layer 820, the sacrificial layer 810 may be exposed to the dissolving solution for an extended duration. This may facilitate the removal of the sacrificial layer 810. As a result, a residue of the sacrificial layer 810 may not be left on the seed layer 910. The residue may cause a process failure in a subsequent process of placing or attaching a semiconductor chip on the carrier substrate 900 or patterning the seed layer 910. That is, it may be possible to reduce a failure rate in a process of fabricating a semiconductor package.

Furthermore, both of the top and bottom surfaces of the photoimageable layer 820 may be exposed to the dissolving solution during the strip process, and thus, the dissolution time of the photoimageable layer 820 may be reduced, even when the photoimageable layer 820 is thickly formed. In other words, it may be possible to reduce a process time for a process of fabricating a semiconductor package.

In addition, since a residue of the sacrificial layer 810 is not formed or a residue of the seed layer 910 is not formed in a subsequent process, the residues, which may cause an electric short problem or an electric open problem, may be absent in a fabricated semiconductor package. That is, the semiconductor package may be fabricated to have a reliable electric connection structure and enhanced operational stability.

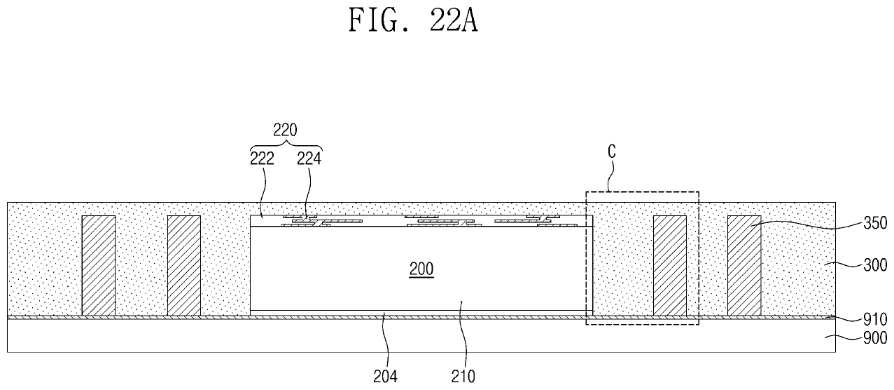

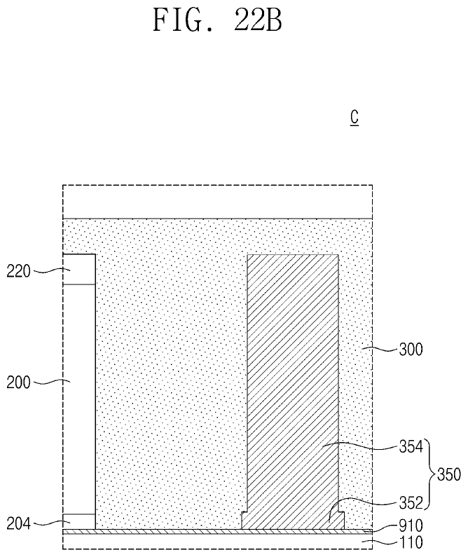

Referring to FIGS. 22A and 22B, the strip process may be further performed in such a way that the photoimageable layer 820 is fully dissolved by the dissolving solution. Accordingly, the top surface of the seed layer 910 and the conductive posts 350 may be exposed.

Thereafter, the first semiconductor chip 200 may be attached to the seed layer 910. The first semiconductor chip 200 may be the first semiconductor chip 200 described with reference to FIG. 7. For example, the first semiconductor chip 200 may include the first base layer 210, the first circuit layer 220 provided on an active surface of the first base layer 210, and the adhesive layer 204 provided on an inactive surface of the first base layer 210. The first semiconductor chip 200 may be attached to the seed layer 910 using the adhesive layer 204.

The mold layer 300 may be formed on the seed layer 910. For example, the mold layer 300 may be formed by depositing or coating an insulating material on the seed layer 910. The mold layer 300 may cover the first semiconductor chip 200 and the conductive posts 350.

Referring back to FIG. 7, the first redistribution substrate 100 may be formed on the mold layer 300. For example, an insulating layer may be formed by depositing an insulating material on the mold layer 300, and the first substrate insulating pattern 110 may be formed by patterning the insulating layer to expose the conductive posts 350. Thereafter, a conductive layer may be formed on the first substrate insulating pattern 110 and may be patterned to form the first substrate interconnection pattern 120. As a result of this process, a first substrate interconnection layer may be formed. The first redistribution substrate 100 may be formed by repeating the process of forming the first substrate interconnection layer.

Thereafter, the seed layer 910 and the carrier substrate 900 may be removed to expose the mold layer 300 and the adhesive layer 204 of the first semiconductor chip 200.

The second redistribution substrate 400 may be attached to the mold layer 300 and the first semiconductor chip 200. The second redistribution substrate 400 may be substantially the same as or similar to the second redistribution substrate 400 described with reference to FIG. 7. For example, the second redistribution substrate 400 may include the base layer 430 and the vertical connection portion 440.

The second semiconductor chip 500 may be mounted on the second redistribution substrate 400. The second semiconductor chip 500 may be substantially the same as or similar to the second semiconductor chip 500 described with reference to FIG. 7. For example, the second semiconductor chip 500 may include the second base layer 510 and the second circuit layer 520, which is provided on the front surface of the second base layer 510.

The outer terminals 150 may be provided on exposed portions of the first substrate interconnection pattern 120. The semiconductor package described with reference to FIGS. 7 and 8 may be fabricated through the afore-described process.

In the case where, as described with reference to FIGS. 18A, 18B, 19A, and 19B, the first redistribution substrate 100 is formed before the formation of the sacrificial layer 810 and the photoimageable layer 820, the semiconductor package may be fabricated to have substantially the same structure as that of FIGS. 1 and 2.

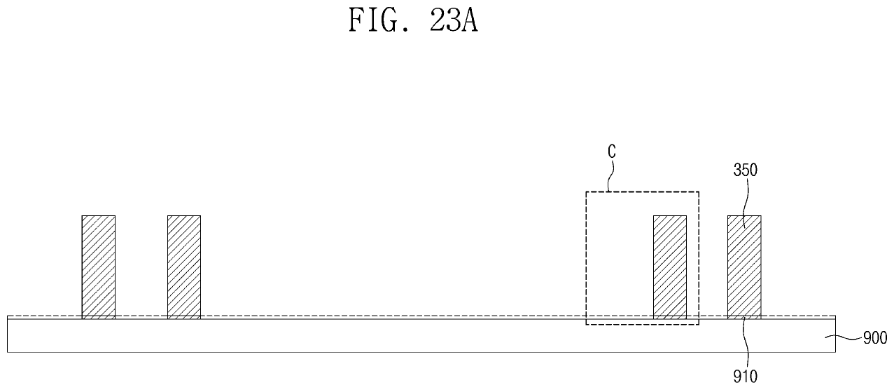

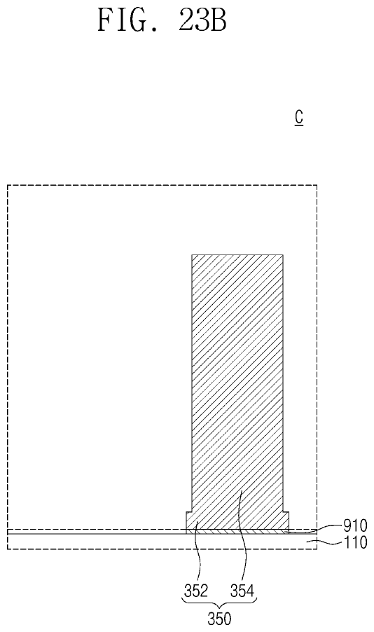

In another embodiment, the entirety of the seed layer 910 may not be removed. Referring to FIGS. 23A and 23B, the strip process may be further performed on the resulting structure of FIGS. 21A and 21B to entirely remove the photoimageable layer 820 using the dissolving solution. Accordingly, the top surface of the seed layer 910 and the conductive posts 350 may be exposed.

Thereafter, the seed layer 910 may be patterned using the conductive posts 350 as an etch mask. As a result of the patterning, the seed layer 910 may be left under only the conductive posts 350. The patterned the seed layer 910 may correspond to the seed/barrier layers 360 described with reference to FIG. 11.

Thereafter, the semiconductor package of FIG. 11 may be fabricated by performing the process described with reference to FIGS. 22A, 22B, and 7.

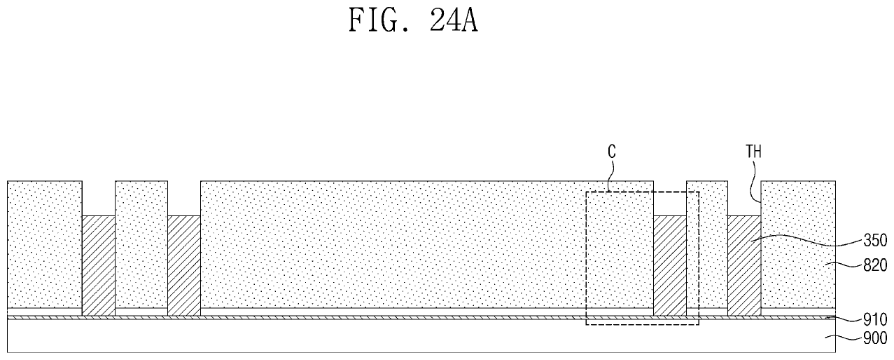

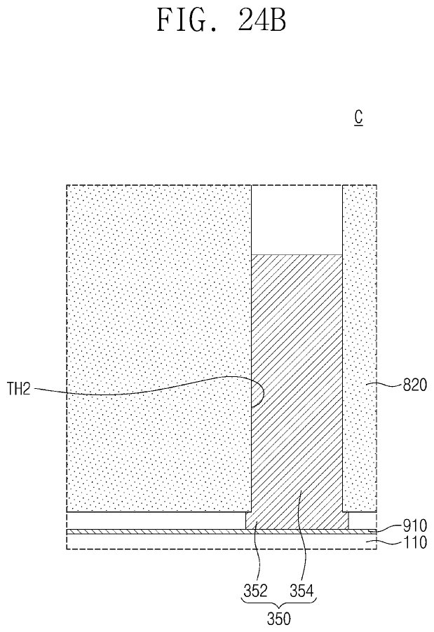

FIG. 24A is a sectional view illustrating a method of fabricating a semiconductor package, according to an embodiment of the inventive concept. FIG. 24B is an enlarged sectional view illustrating a portion ‘C’ of FIG. 24A.

Referring to FIGS. 24A and 24B, a first process may be performed on the resulting structure of FIGS. 19A and 19B to remove the sacrificial layer 810. For example, the first process may be a strip process. The strip process may be a wet etching process. In more detail, first dissolving solution may be used to dissolve the sacrificial layer 810. Here, the first dissolving solution may dissolve the sacrificial layer 810 in an inward direction from a side of the sacrificial layer 810 toward an inner portion of the sacrificial layer 810. The photoimageable layer 820 may not be removed during the process of removing the sacrificial layer 810. For example, the first dissolving solution, which is used to remove the sacrificial layer 810, may be different from second dissolving solution, which is used to remove the photoimageable layer 820. As an example, the sacrificial layer 810 may be formed of or include a material different from the photoimageable layer 820. In an embodiment, the photoimageable layer 820 may be formed of or include a photoimageable material, and the sacrificial layer 810 may be formed of or include an insulating material different from the photoimageable material. The strip process may be further performed until the sacrificial layer 810 is entirely removed by the first dissolving solution. Accordingly, the entire top surface of the seed layer 910 and the entire bottom surface of the photoimageable layer 820 may be exposed.

In another embodiment, the first process may include an optical treatment process or a thermal treatment process. The sacrificial layer 810 may be gasified or liquefied by the optical treatment process or the thermal treatment process.

Next, a second process may be performed to remove the photoimageable layer 820. For example, the second process may include a strip process. The strip process may be a wet etching process. In more detail, the second dissolving solution may be used to dissolve or liquefy the photoimageable layer 820. Here, the second dissolving solution may dissolve the photoimageable layer 820 in a direction from the top surface of the photoimageable layer 820 and the exposed bottom surface of the photoimageable layer 820 toward an inner portion of the photoimageable layer 820. Since the sacrificial layer 810 is removed, the dissolving solution may be more easily supplied into a space between the seed layer 910 and the photoimageable layer 820. The strip process may be further performed such that the photoimageable layer 820 is entirely removed by the second dissolving solution. Accordingly, the top surface of the seed layer 910 and the conductive posts 350 may be exposed.

In another embodiment, the second process may be performed before the first process is finished. That is, the sacrificial layer 810 may not be entirely removed when the second process begins. The first and second processes may be further performed to remove a remaining portion of the sacrificial layer 810 and the photoimageable layer 820.

Thereafter, a semiconductor package may be fabricated by performing the process described with reference to FIGS. 22A, 22B, and 7.

According to an embodiment of the inventive concept, since the sacrificial layer 810 is first removed, both of the top and bottom surfaces of the photoimageable layer 820 may be exposed to the second dissolving solution. Accordingly, the dissolution time of the photoimageable layer 820 may be reduced. That is, any portion of the sacrificial layer 810 may not be left after the strip process, and the sacrificial layer 810 and the photoimageable layer 820 may be more effectively removed. Furthermore, the fabrication process of a semiconductor package may be conducted with reduced process time.

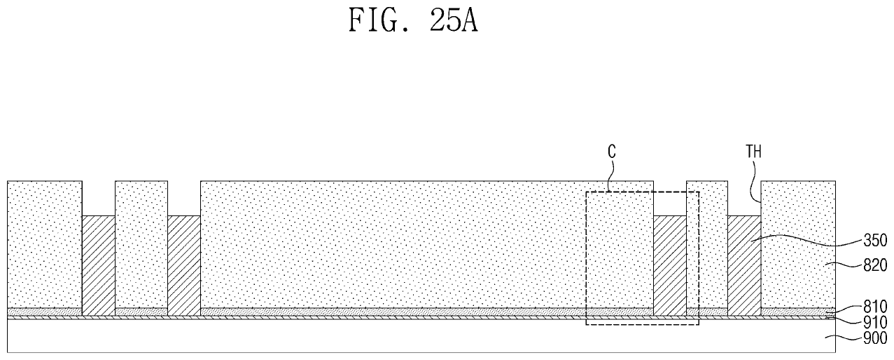

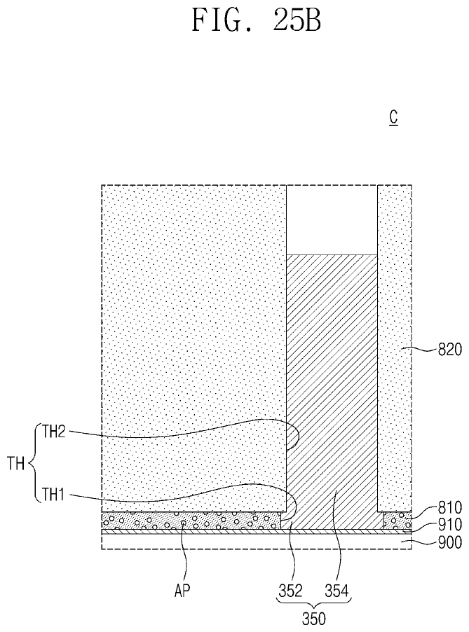

FIG. 25A is a sectional view illustrating a method of fabricating a semiconductor package, according to an embodiment of the inventive concept. FIG. 25B is an enlarged sectional view illustrating a portion ‘C’ of FIG. 25A.

Referring to FIGS. 25A and 25B, a third process may be performed on the resulting structure of FIGS. 19A and 19B to weaken an adhesive strength between the sacrificial layer 810 and the seed layer 910. The third process may be a pre-treatment process, which is performed on the sacrificial layer 810 before the strip process of removing the sacrificial layer 810 and the photoimageable layer 820. The third process may include an optical treatment process or a thermal treatment process. The optical treatment process or the thermal treatment process may be performed to form at least one air pore AP in the sacrificial layer 810. In an embodiment, the air pores AP may be distributed in the sacrificial layer 810. Furthermore, the air pores AP may be distributed on a surface of the sacrificial layer 810 (preferably, a surface of the sacrificial layer 810 facing the seed layer 910). Due to the presence of the air pores AP, a contact area between the sacrificial layer 810 and the seed layer 910 may be reduced, and this may lead to deterioration in the adhesive strength between the sacrificial layer 810 and the seed layer 910. In an embodiment, the sacrificial layer 810 may be formed of or include a material different from the photoimageable layer 820. For example, the photoimageable layer 820 may be formed of or include a photoimageable material, and the sacrificial layer 810 may be formed of or include an insulating material different from the photoimageable material.

Thereafter, a strip process may be performed on the sacrificial layer 810 and the photoimageable layer 820. The sacrificial layer 810 and photoimageable layer 820 may be removed by the strip process, and as a result, the seed layer 910 and the conductive posts 350 may be exposed.

According to an embodiment of the inventive concept, the adhesive strength between the sacrificial layer 810 and the seed layer 910 may be weakened, and thus, the sacrificial layer 810 may be easily removed or delaminated during the strip process. Accordingly, any portion of the sacrificial layer 810 may not be left after the strip process, and the semiconductor package may be fabricated with a low failure rate.

In another embodiment, physical and chemical characteristics of the sacrificial layer 810 may be changed by the third process. The third process may include an optical treatment process or a thermal treatment process. For example, the optical treatment process or the thermal treatment process may cause a phase change of at least a portion of the sacrificial layer 810. For example, at least a portion of the sacrificial layer 810 may be gasified or liquefied by the optical treatment process or the thermal treatment process. Alternatively, a molecular structure of a material constituting the sacrificial layer 810 may be changed by the optical treatment process or the thermal treatment process. Due to the change of the physical and chemical characteristics of the sacrificial layer 810, the adhesive strength between the sacrificial layer 810 and the seed layer 910 may be weakened.

A strip process may be performed on the sacrificial layer 810 and the photoimageable layer 820. The sacrificial layer 810 and the photoimageable layer 820 may be removed by the strip process, and as a result, the seed layer 910 and the conductive posts 350 may be exposed.

Thereafter, a semiconductor package may be fabricated by performing the process described with reference to FIGS. 22A, 22B, and 7.

In a method of fabricating a semiconductor package according to an embodiment of the inventive concept, a sacrificial layer, which is in contact with a top surface of a seed layer, may be formed of a material that can be dissolved at a high rate by dissolving solution. Furthermore, since the sacrificial layer is removed before removing a photoimageable layer, exposure time of the sacrificial layer to the dissolving solution may be increased. Accordingly, it may be possible to easily remove the sacrificial layer. Thus, a residue of the sacrificial layer may not be left on the seed layer. Accordingly, a semiconductor package may be fabricated with a low failure rate.

In addition, an adhesive strength between the sacrificial layer and the seed layer may be weakened, and thus, the sacrificial layer may be easily removed or delaminated in the strip process. Accordingly, the sacrificial layer may not be left after the strip process, and it may be possible to reduce a failure rate in a process of fabricating a semiconductor package.

In a method of fabricating a semiconductor package according to an embodiment of the inventive concept, during the strip process, both of top and bottom surfaces of the photoimageable layer may be exposed to the dissolving solution, and thus, the dissolution time of the photoimageable layer may be reduced. Therefore, it may be possible to reduce a process time for a process of fabricating a semiconductor package.

In a semiconductor package according to an embodiment of the inventive concept, there may be no residue issue, such as a residue of the sacrificial layer or a residue of the seed layer formed in a subsequent process, and thus, it may be possible to prevent an electric short or open issue from occurring in a fabricated semiconductor package. Therefore, the semiconductor package may be fabricated to have a reliable electric connection structure and enhanced operational stability.

While example embodiments of the inventive concept have been particularly shown and described, it will be understood by one of ordinary skill in the art that variations in form and detail may be made therein without departing from the spirit and scope of the attached claims.

1. A method of fabricating a semiconductor package, comprising:
providing a substrate;
forming a seed layer to cover a top surface of the substrate;
sequentially stacking a sacrificial layer and a photoimageable layer on the seed layer;
forming a penetration hole to penetrate the photoimageable layer and the sacrificial layer and expose the seed layer;
forming a conductive post in the penetration hole;
performing a first process to remove at least a portion of the sacrificial layer;
performing a second process to remove the photoimageable layer; and
patterning or removing the seed layer.

2. The method of claim 1, wherein the first process and the second process are simultaneously performed within a single strip process, and
the strip process is performed to remove the sacrificial layer and the photoimageable layer using dissolving solution.

3. The method of claim 2, wherein, in the strip process, the sacrificial layer is fully removed before fully removing the photoimageable layer.

4. The method of claim 2, wherein a dissolution rate of the sacrificial layer by the dissolving solution is faster than a dissolution rate of the photoimageable layer by the dissolving solution.

5. The method of claim 1, wherein the first process is performed before the second process, and
at least a portion of the sacrificial layer is removed by the first process.

6. The method of claim 5, wherein the first process comprises a thermal treatment process or an optical treatment process performed on the sacrificial layer.

7. The method of claim 5, wherein an adhesive strength between the sacrificial layer and the seed layer is weakened as a result of the first process being performed.

8. The method of claim 5, wherein the first process is performed to form an air pore in the sacrificial layer.

9. The method of claim 5, wherein the first process is performed to gasify at least a portion of the sacrificial layer.

10. The method of claim 5, wherein:
the second process is performed to remove a remaining portion of the sacrificial layer,
the second process comprises removing the remaining portion of the sacrificial layer and the photoimageable layer using the dissolving solution, and
a dissolution rate of the sacrificial layer by the dissolving solution is faster than a dissolution rate of the photoimageable layer by the dissolving solution.

11. The method of claim 1, wherein:
the first process is performed before the second process, and
the sacrificial layer is fully removed by the first process.

12. (canceled)

13. The method of claim 1, wherein the penetration hole comprises:
a first hole formed in the sacrificial layer; and
a second hole formed in the photoimageable layer,
wherein a horizontal width of the first hole is larger than a horizontal width of the second hole.

14. (canceled)

15. A method of fabricating a semiconductor package, comprising:
providing a substrate;
sequentially stacking a sacrificial layer and a photoimageable layer on the substrate;
forming a penetration hole to penetrate the photoimageable layer and the sacrificial layer;
forming a conductive post in the penetration hole;
performing a first process on the sacrificial layer to weaken an adhesive strength between the sacrificial layer and the substrate; and
performing a second process to remove the sacrificial layer and the photoimageable layer.

16. The method of claim 15, wherein the first process comprises a thermal treatment process or an optical treatment process performed on the sacrificial layer.

17. The method of claim 15, wherein the first process is performed to form an air pore in the sacrificial layer.

18. The method of claim 15, wherein the first process is performed to gasify at least a portion of the sacrificial layer.

19. (canceled)

20. The method of claim 15, wherein the second process comprises a strip process of removing the sacrificial layer and the photoimageable layer using dissolving solution.

21. (canceled)

22. The method of claim 20, wherein a dissolution rate of the sacrificial layer by the dissolving solution is faster than a dissolution rate of the photoimageable layer by the dissolving solution.

23-26. (canceled)

27. The method of claim 15, wherein the penetration hole comprises:
a first hole formed in the sacrificial layer; and
a second hole formed in the photoimageable layer,
wherein a width of the first hole is larger than a width of the second hole.

28. (canceled)

29. A method of fabricating a semiconductor package, comprising:
providing a substrate;
sequentially stacking a sacrificial layer and a photoimageable layer on the substrate;
forming a penetration hole to penetrate the photoimageable layer and the sacrificial layer, a width of the penetration hole in the sacrificial layer being larger than a width of the penetration hole in the photoimageable layer;
forming a conductive post in the penetration hole; and
performing a strip process, in which a same dissolving solution is used, to remove the photoimageable layer and the sacrificial layer,
wherein, in the strip process, the sacrificial layer is fully removed before fully removing the photoimageable layer.

30-39. (canceled)
